(19) United States
(12) Patent Application Publication
(10) Pub. No.: US 2002/0136255 A1
(43) Pub. Date: Sep. 26, 2002

(54) Semiconductor laser, optical element provided with the same and optical pickup provided with the optical element

(75) Inventors: Toru Takayama, Nara-shi (JP); Kenji Orita, Takatsuki-shi (JP); Masaaki Yuri, Ibaraki-shi (JP)

Correspondence Address: MERCHANT & GOULD PC, P.O. BOX 2903, MINNEAPOLIS, MN, 55402-0903, US

(73) Assignee: Matsushita Electric Industrial Co., Ltd., Kadoma-shi (JP)

(21) Appl. No.: 10/105,734

(22) Filed: Mar. 22, 2002

(30) Foreign Application Priority Data
Mar. 23, 2001 (JP) 2001-084805

(51) Int. Cl. H01L 29/06; H01L 31/0328; H01L 31/109; H01L 21/00

(52) U.S. Cl. 372/45; 257/15

(57) ABSTRACT

A semiconductor laser includes a gain region, a phase control region and a DBR region. The semiconductor laser includes an active layer of multiple quantum wells of Ga_{0.7}Al_{0.3}As barrier layers and GaAs well layers, a p-type Ga_{0.5}Al_{0.5}As second cladding layer and a p-type Ga_{0.7}Al_{0.3}As first light-guiding layer. Furthermore, a p-type Ga_{0.8}Al_{0.2}As diffraction grating layer subjecting waveguide light to a distributed Bragg reflection is layered on the first light-guiding layer. This diffraction grating layer is arranged at least at a region other than a region opposite the optical waveguide of the active layer in the gain region (region into which the current is supplied).

### BACKGROUND OF THE INVENTION

1. Field of the Invention

The present invention relates to a semiconductor laser, an optical element provided with the same, as well as to an optical pickup provided with that optical element, and used for an optical information processing device, such as an optical disk system or the like.

2. Related Background Art

There is a demand for laser light sources emitting light at short wavelengths (i.e. blue light) with which the focus spot diameter on the optical disk can be made smaller than with light of the red or infrared region, or in other words for blue-light emitting laser light sources, as light sources for the recording and reproduction of high-density optical disks. Such blue-light emitting laser light sources are useful for increasing the recording density and improving the reproduction characteristics of optical disks. As one useful way to obtain such laser light of the blue region, there is the method of converting light of the infrared region into shorter wavelength light in the blue region by second harmonic generation (SHG). At present, non-linear optical materials as typified by LiNbO₃ are used widely for SHG elements. Usually, in such SHG elements made of LiNbO₃, a grating is formed by ion exchange in accordance with the wavelength of the infrared light used as the input light, and such elements are configured such that there is an integer ratio between the wavelength of the infrared light in the SHG waveguide, the wavelength of the blue light generated by the SHG element, and the grating pitch. Consequently, the wavelength of the infrared light taken as the excitation light is restricted by the SHG element to a small range. For this reason, a DBR (Distributed Bragg Reflector) semiconductor laser, which has a high oscillation wavelength selectivity, oscillates at a single longitudinal mode, and in which changes of the oscillation wavelength due to temperature can be adjusted, is used as the excitation light source emitting the infrared light. The efficiency at which infrared light is converted to blue light by the SHG element ranges from several percent to several dozen percent, and is generally proportional to the optical power input into the nonlinear optical element. In particular, to attain blue light of about 5 mW, which is necessary when reproducing high-density optical disks, with an SHG element, the power of the infrared excitation light should be at least about 50 mW. In order to obtain, with an SHG element, blue light of about several dozen mW as necessary for recording, the power of the infrared excitation light should be at least 100 mW. Therefore, there is a demand for infrared light emitting DBR semiconductor lasers, as used for light sources for recording/reproduction of high-density optical disks, that have high-power output characteristics of at least 100 mW.

DBR semiconductor lasers that can produce laser light in the infrared region are disclosed for example in JP H6-53619A. As shown in FIG. 22, such infrared light emitting DBR semiconductor lasers are partitioned into three regions with respect to the optical resonance direction, namely a gain region 1010, a phase control region 1011, and a DBR region 1012. As for the layering structure, an n-type GaAs buffer layer 1002 of 0.5 μm thickness, an n-type AlGaAs first cladding layer 1003 (with an Al content (mol) of 0.45) of 1.5 μm thickness, an active layer 1004, a p-type AlGaAs second cladding layer 1005 (with an Al content (mol) of 0.4) of 0.04 μm thickness, and a p-type AlGaAs light-guiding layer 1006 (with an Al content (mol) of 0.15) of 0.25 μm thickness are layered on an n-type GaAs substrate 1001. These layers are formed by MBE (molecular beam epitaxy). Diffraction gratings g1 and g2 are provided on the surface of the p-type AlGaAs optical guiding layer 1006. Regarding the method for forming these diffraction gratings g1 and g2, first a resist is applied on the optical guiding layer 1006 and patterned by two-beam interference exposure, and a diffraction grating g1 with a depth of 10 Å and a pitch of 2440 Å is formed by etching with RIBE (reactive ion beam etching). Then, patterning is performed using another resist different from the resist used for the two-beam interference exposure, and a stripe-shaped diffraction grating g2 of 300 μm width parallel to the diffraction grating g1 is formed, again by RIBE etching. Thus, diffraction gratings g1 and g2 of the same pitch but different depth are formed. On the light-guiding layer 1006, a p-type AlGaAs cladding layer 1007 (with an Al composition of 0.45) of 1.5 μm thickness is layered. This cladding layer 1007 is formed by LPE (liquid phase epitaxy). A p-type GaAs contact layer 1008 of 0.5 μm thickness and an electrode 1009 are arranged on the cladding layer 1007. The contact layer 1008 and the electrode 1009 are partitioned into three regions, such that current can be supplied independently into the gain region 1010, the phase control region 1011 and the DBR region 1012. Numeral 1013 denotes a electric layer that is provided on the surface of the substrate 1001.

In this structure, laser oscillation is generated by supplyding a laser driving current to the electrodes 1009 of the gain region 1010 and the phase control region 1011. When doing so, the oscillation wavelength with the highest reflectance is selected by Bragg reflection with the diffraction grating g2, achieving a single longitudinal mode oscillation. Moreover, by supplying current to the electrode 1009 of the DBR region 1012, it is possible to change the effective refractive index of the DBR region in which the diffractive grating g2 is formed, and to change the selected wavelength. Thus, the oscillation wavelength can be changed by several nm. By changing the current supplied to the electrode 1009 of the phase control region 1011 in order to suppress mode hopping in this situation, it is possible to adjust the phase of the guided light. Consequently, with the DBR semiconductor laser in FIG. 22, it is possible to obtain a semiconductor laser, with which the oscillation wavelength can be changed for several nm while suppressing mode hopping, and with which single longitudinal mode oscillation with wavelength selectivity is possible. In this DBR semiconductor laser, a resonator is formed in which the cleaved surface 1013 on the side of the gain region 1010 and the DBR due to the diffraction grating g2 in the DBR region 1012 serve as the two reflection mirrors, and guided light is amplified in the gain region 1010, achieving laser oscillation.

As mentioned above, there is a demand for semiconductor lasers serving as SHG light sources that have high-power output characteristics of at least 100 mW. In order to realize such high-power output characteristics, it is necessary to precisely control the shape of the optical distribution of the laser light propagated along the waveguide. The size of the optical distribution region within the plane parallel to the active layer ordinarily is controlled by the effective refractive index difference Δn between the inside and the outside of the stripe-shaped region into which current is supplied (in the following also referred to as “current supply stripe”).

In the following, within the plane defined by the cleaved surface of the resonator, the direction parallel to the crystal growth plane is taken as the transverse direction, and the direction perpendicular to the crystal growth plane is taken as the vertical direction. Here, if the effective refractive index difference Δn is large (more specifically, when Δn>1×10⁻²), then the optical distribution is strongly confined within the current supply stripe of the active layer, the spread of the optical distribution in the transverse direction is small, and the maximum power density of the laser light in the central region of the optical distribution becomes large. In this case, the output level at which the cleaved surface of the resonator (in the conventional example shown in FIG. 22, the cleaved surface 1013 on the side of the gain region 1010) is destroyed by COD (Catastrophic Optical Damage), in which it is melted down due to the optical power of the laser, is reduced, so that it becomes difficult to achieve a high-power output semiconductor laser.

Conversely, when the effective refractive index difference Δn is small, the optical distribution is only weakly confined within the current supply stripe in the active layer, and the spread of the optical distribution in the transverse direction becomes large. In general, when semiconductor lasers are operated at high output powers, the carrier density injected into the active layer becomes large, so that the effective refractive index within the current supply stripe is reduced due the plasma effect. Consequently, when the effective refractive index difference Δn is too small (more specifically, when Δn<3×10⁻³), the plasma effect causes the effective refractive index within the current supply stripe to become smaller than the effective refractive index outside the current supply stripe, making it an anti-waveguide, so that a stable basic transverse mode cannot be attained.

Thus, to produce a high-output power semiconductor laser stably with high yield, the effective refractive index difference Δn should be controlled to be in the order of 10⁻³, and preferably the effective refractive index difference Δn should be controlled precisely to about 3×10⁻³ to 5×10⁻³. Here, the effective refractive index of the waveguide mode of the laser light is influenced to a large extent by the spread of the optical distribution in the vertical direction. That is to say, when the optical distribution spreads widely into the cladding layers, which have a lower refractive index than the active layer, the effective refractive index of the waveguide mode becomes small. Consequently, to control the effective refractive index difference Δn to the order of 10⁻³, it is necessary also to control precisely the spread of the optical distribution in the vertical direction.

In the conventional example shown in FIG. 22, the p-type AlGaAs second cladding layer 1005 (with an Al content (mol) of 0.4) of 0.04 μm thickness, and the p-type AlGaAs light-guiding layer 1006 (with an Al content (mol) of 0.15) of 0.25 μm thickness are layered on an n-type GaAs substrate 1001. In this structure, the diffraction grating g2 is formed in the light-guiding layer 1006 in the waveguide, and the effect that the region where this diffraction grating g2 is formed acts as a reflection mirror for the laser light makes it possible to function as a DBR semiconductor laser. In the light-guiding layer 1006, the portion in which the diffraction grating g1 of 10 Å thickness is formed in the waveguide has a thickness that is substantially the same as the thickness determined by the crystal growth. The laser light is emitted from the side where this diffraction grating g1 of 10 Å thickness is formed in the light-guiding layer 1006. In the case of such a DBR semiconductor laser, the Al content of the light-guiding layer 1006 is low at 0.15, and its thickness is thick at 0.25 μm, so that its refractive index is relatively higher than that of the second cladding layer 1005, and a layer of large thickness is present near the active layer 1004. With this structure, the optical distribution is influenced by the light-guiding layer 1006 with high refractive index, so that the optical distribution spreads widely in vertical direction. When, in this manner, the optical distribution is influenced more by the layer structure outside the active layer, then the precise control of the effective refractive index difference Δn is impeded, and a decrease of the yield when producing such high-power output DBR semiconductor lasers may be the result.

Furthermore, in order to solve this problem, it is conceivable to confine the optical distribution in transverse direction with a buried hetero structure in the conventional structure shown in FIG. 22. However, with such a buried hetero structure, the effective refractive index difference Δn becomes very large, and the optical distribution becomes strongly confined in the horizontal direction, so that (1) during high-power output operation, this may give rise to spatial hole-burning of carriers in the active layer 1004, leading to non-linear current—optical output characteristics, and (2) due to the strong confinement of the light in the transverse direction, the optical density at the cleaved surface 1013 of the gain region 1010 becomes high, which may lead to melt-down of the cleaved surface 1013 on the side of the gain region 1010, or other problems may occur. Accordingly, it is difficult to realize a DBR semiconductor laser with high output power.

### SUMMARY OF THE INVENTION

A semiconductor laser in accordance with the present invention includes an active layer emitting light due to electron-hole recombination caused by a supplied current; a first semiconductor layer, which is provided above the active layer and which confines carriers injected into the active layer as well as light emitted in the active layer within the active layer; a second semiconductor layer, which is provided above the first semiconductor layer and which comprises a diffraction grating; wherein the second semiconductor layer is arranged above the first semiconductor layer in a region that is other than at least a predetermined region, the predetermined region being a region arranged in opposition to an optical waveguide of the active layer in a gain region provided, with respect to an optical resonanse direction, on a side of a light emission end face of the laser.

With this configuration, the second semiconductor layer, which is formed relatively thickly in order to avoid the coupling coefficient between the waveguide and the diffraction grating becoming too small is not provided in a region opposite the optical waveguide of the active layer in the gain region, thus reducing the reflectance at the diffraction grating. That is to say, there is no thick semiconductor layer influencing the optical distribution near the optical waveguide in the gain region, so that the optical distribution region can be controlled precisely and light can be confined in the transverse direction. Consequently, there is no need to confine the optical distribution in the transverse direction with a buried hetero structure, so that the risk of the laser light emitting end face melting down can be reduced. Thus, it becomes possible to provide a semiconductor laser with high output power and high yield.

It is preferable that the semiconductor laser of the present invention further includes a third semiconductor layer, which is provided between the first semiconductor layer and the second semiconductor layer, and which is less susceptible to oxidation than the first semiconductor layer. With this configuration, it is possible to suppress oxidation of the crystal regrowth interface when regrowing the crystal after forming the second semiconductor layer on top of the third semiconductor layer. Thus, it is possible to prevent the resistance of the crystal regrowth interface from becoming high.

An optical element in accordance with the present invention includes the above-described semiconductor laser, and a non-linear optical element that shortens a wavelength of light emitted from the semiconductor laser.

With this optical element, it is possible to attain light of short wavelengths at high output powers, which can be used as a light source for recording and reproduction of high-density optical disks, for example.

Furthermore, an optical pickup in accordance with the present invention includes the above-described optical element and a light-receiving portion for detecting a signal of information recorded on a recording medium.

With this optical pickup, it is possible to provide an optical pickup for a high-density optical disk system capable of recording and reproducing.

### BRIEF DESCRIPTION OF THE DRAWINGS

FIG. 1 is a perspective view of a semiconductor laser according to an embodiment of the present invention.

FIG. 2 is a top view of the semiconductor laser shown in FIG. 1, illustrating the stripe pattern of the stripe-shaped window.

FIG. 3 illustrates the proportion of light reflected at the cleaved surface on the side of the DBR region that is fed back into the waveguide (effective reflectance) as a function of the angle θ defined by the stripe-shaped window 10a and the normal on the cleaved surface.

FIGS. 4A to 4G are perspective views of the steps for manufacturing the semiconductor laser shown in FIG. 1.

FIG. 5 is a perspective view of a semiconductor laser according to another embodiment of the present invention.

FIG. 6 is a perspective view of a semiconductor laser according to yet another embodiment of the present invention.

FIG. 7 is a top view of the semiconductor laser shown in FIG. 6, illustrating the stripe pattern of a plurality of stripe-shaped windows.

FIG. 8 is a perspective view of a semiconductor laser according to yet another embodiment of the present invention.

FIG. 9 is a perspective view of a semiconductor laser according to yet another embodiment of the present invention.

FIG. 10 is a top view of the semiconductor laser shown in FIG. 9 illustrating the stripe pattern of the stripe-shaped window.

FIGS. 11A to 11G are perspective views of the steps for manufacturing the semiconductor laser shown in FIG. 9.

FIG. 12 is a perspective view of a semiconductor laser according to yet another embodiment of the present invention.

FIG. 13 is a perspective view of a semiconductor laser according to yet another embodiment of the present invention.

FIG. 14 is a top view of the semiconductor laser shown in FIG. 13, illustrating the stripe pattern of a plurality of stripe-shaped windows.

FIG. 15 is a lateral view diagrammatically showing the configuration of an optical element in accordance with an embodiment of the present invention.

FIG. 16 is a lateral view diagrammatically showing the configuration of an optical element in accordance with another embodiment of the present invention.

FIG. 17 is a lateral view diagrammatically showing the configuration of an optical element in accordance with yet another embodiment of the present invention.

FIG. 18 is a lateral view diagrammatically showing the configuration of an optical element in accordance with yet another embodiment of the present invention.

FIG. 19 is a lateral view diagrammatically showing the configuration of an optical pickup in accordance with an embodiment of the present invention.

FIG. 20 is a lateral view diagrammatically showing the configuration of an optical pickup in accordance with another embodiment of the present invention.

FIG. 21 is a lateral view diagrammatically showing the configuration of an optical pickup in accordance with yet another embodiment of the present invention.

FIG. 22 is a cross-sectional view of a conventional semiconductor laser.

### DETAILED DESCRIPTION OF THE INVENTION

The following is a description of preferred embodiments of the present invention, with reference to the accompanying drawings.

First Embodiment

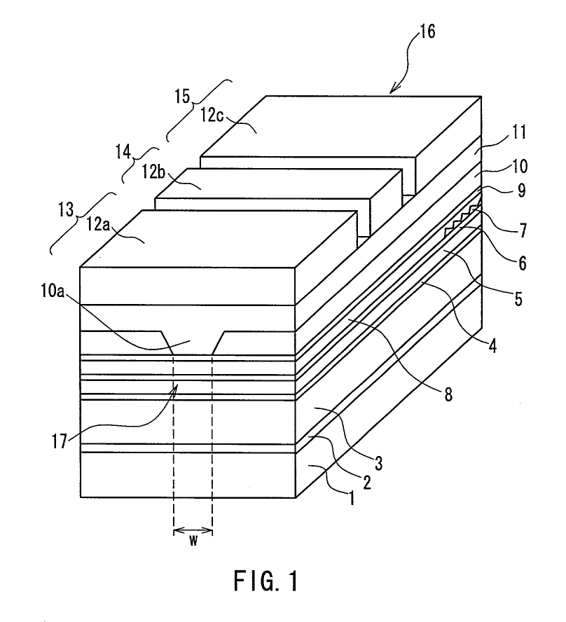

FIG. 1 is a perspective view of a DBR semiconductor laser incorporating a diffraction grating within a waveguide in accordance with a first embodiment of the present invention. This DBR semiconductor laser is partitioned into three regions with respect to the optical resonance direction, namely a gain region 13, a phase control region 14, and a DBR region 15. In this structure, a resonator is formed by a cleaved front surface 17 near the gain region 13 and a DBR due to the diffraction grating in the DBR region 15, which serve as the two reflective mirrors, and guided light is amplified in the gain region 13, thus achieving laser oscillation. The following is an explanation of the layering structure of this semiconductor laser. An n-type GaAs buffer layer 2, an n-type Ga_{0.5}Al_{0.5}As first cladding layer 3, an active layer 4 of multiple quantum wells of Ga_{0.7}Al_{0.3}As barrier layers and GaAs well layers, a p-type Ga_{0.5}Al_{0.5}As second cladding layer (first semiconductor layer) 5, and a p-type Ga_{0.7}Al_{0.3}As first light-guiding layer (third semiconductor layer) 6 may be layered on an n-type GaAs substrate 1. Furthermore, a p-type Ga_{0.8}Al_{0.2}As diffraction grating layer (second semiconductor layer) 7 for subjecting the guided light to distributed Bragg reflection is provided on top of the first light-guiding layer 6. This diffraction grating layer 7 is provided only in the DBR region 15, and not in the gain region 13 or in the phase control region 14. This means that on the first light-guiding layer 6, there is a diffraction grating layer formation region in which the diffraction grating layer 7 is formed and a diffraction grating layer non-formation region in which the diffraction grating layer 7 is not formed. A p-type Ga_{0.5}Al_{0.5}As second light guiding layer 8 and a p-type Ga_{0.8}Al_{0.2}As third cladding layer 9 may be provided on the diffraction grating layer 7 (and also on the diffraction grating layer non-formation region). On top of that, an n-type Ga_{0.4}Al_{0.6}As current blocking layer 10 for current constriction provided with a stripe-shaped window 10a is provided. Furthermore, a p-type Ga_{0.44}Al_{0.56}As fourth cladding layer (fourth semiconductor layer) 11 as well as p-type GaAs contact layers 12a to 12c partitioned into three with respect to the optical resonance direction may be provided on top of the current blocking layer 10 including the stripe-shaped window 10a. The p-type GaAs contact layers 12a and 12b partition the diffraction grating layer non-formation region into two regions with respect to the optical resonance direction, whereas the p-type GaAs contact layer 12c is provided on the diffraction grating layer formation region. In this embodiment, the diffraction grating layer 7 is provided only in the DBR region 15 and not in the gain region 13 and the phase control region 14, but it is sufficient if the diffraction grating layer 7 is arranged such that it has no influence on the optical distribution in the gain region 13. Consequently, the diffraction layer 7 should be provided in a region that is at least other than the region opposite the optical waveguide of the active layer 4 in the gain region 13 (region in which current is supplied). Furthermore, the DBR region 15 should be provided with a diffraction grating, so that the diffraction grating layer 7 should be provided at least in the DBR region 15.

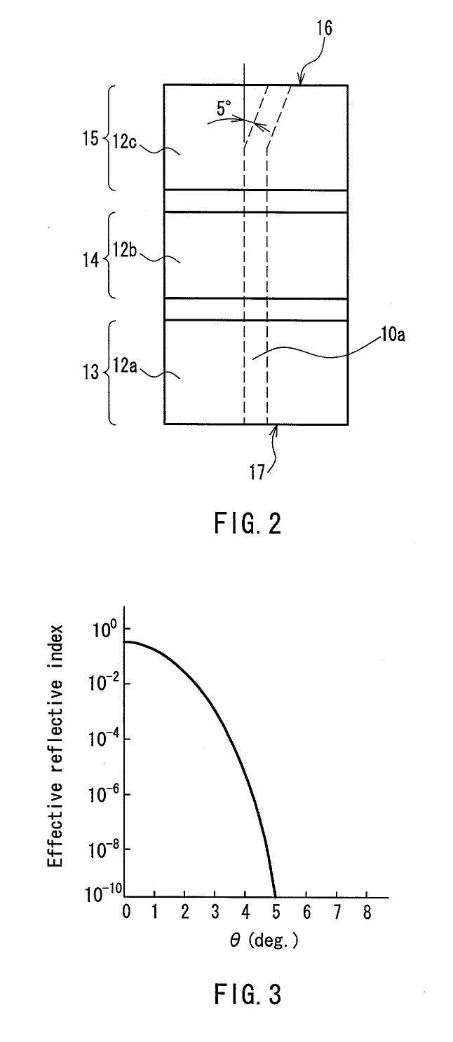

Furthermore, as shown in FIG. 2, the stripe-shaped window 10a for forming the waveguide intersects with the cleaved rear surface 16 at an angle of 5° with respect to the normal on the cleaved rear surface 16 on the side of the DBR region 15 in the semiconductor laser. That is to say, the current blocking layer 10 is provided with a stripe-shaped window 10a that is bent midway at an angle of 5° with respect to the normal on the cleaved rear surface 16 within a plane that is parallel to the active layer 4. The bent part of the stripe-shaped window 10a has a length of 300 μm. The angle defined by the stripe-shaped window 10a and the normal on the cleaved rear surface 16 is preferably at least 1° and at most 10°. The length of the bent part of the stripe-shaped window 10a is preferably at least 100 μm.

With this structure, current supplied from the p-type GaAs contact layer 12a of the gain region 13 reaches the active layer 4 below the p-type GaAs contact layer 12a after being constricted to the stripe-shaped window 10a by the n-type Ga_{0.4}Al_{0.6}As current blocking layer 10, and an emission occurs in the stripe-shaped region of the active layer 4, into which current has been supplied (i.e. in the current supply stripe of the active layer 4). As a result of being subjected to wavelength selection due to the distributed Bragg reflection by the diffraction grating layer 7, the generated light oscillates in a single longitudinal mode.

The following is an explanation of the characteristics of this DBR semiconductor laser, broken down into its structural parts.

1A. Configuration in Waveguide Direction

DBR Region

To use DBR semiconductor lasers as SHG excitation light sources, it is necessary to control the laser oscillation wavelength such that a high second harmonic conversion efficiency can be attained with the non-linear optical element used for SHG. The wavelength of the distributed Bragg reflected wave can be controlled with the amount of current supplied to the GaAs contact layer 12c. This is because if the current supply is carried out mainly at the GaAs contact layer 12c, then it is possible to alter the spacing of the diffraction grating formed in the diffraction grating layer 7 by the generation of heat. This means, to change the wavelength of the laser oscillation toward longer wavelengths, the current supplied to the GaAs contact layer 12c should be increased, whereas to change the wavelength of the laser oscillation toward shorter wavelengths, the current supplied to the GaAs contact layer 12c should be decreased.

Here, if the length of the DBR region 15 in the optical resonance direction is long, then a high reflectance can be attained because of the increased coupling between the diffraction grating and the guided optical wave, but if it is too long, then the dissipated heat increases, and the variability of the oscillation wavelength by heat generation is harmed. Consequently, it is preferable that the length of the DBR region is set to at least 100 μm and at most 700 μm. In the DBR semiconductor laser according to this embodiment, the length of the DBR region is set to 300 μm. In this embodiment, by changing the value of the current supplied to the GaAs contact layer 12c for example between 0 mA and 100 mA, the oscillation wavelength can be tuned in a range of about 3 nm.

Phase Control Region

When changing the distributed Bragg wavelength, there may be two or more wavelengths for which a high reflectance can be attained near the desired laser oscillation wavelength. In this situation, mode-hopping to the wavelength with the higher gain may occur, and there is the possibility that the laser oscillation wavelength deviates from the desired oscillation wavelength. To prevent this, the value of the current supplied to the GaAs contact layer 12b in the phase control region 14 is changed, the effective length of the waveguide below the GaAs contact layer 12b is changed by heat generation, and controlled such that the phase condition for laser oscillation is satisfied only by the desired oscillation wavelength. Here, when the phase control region 14 is long with respect to the optical resonance direction, then the dissipated heat increases, and the variability of the oscillation wavelength by heat generation is harmed. Conversely, if the phase control region 14 is short, then the change of the effective waveguide length caused by the heat generation may be too small. Consequently, it is preferable that the length of the phase control region 14 is at least 100 μm and at most 700 μm. In the present embodiment, the length of the phase control region 14 is set to 250 μm.

Configuration of the Diffraction Grating

Ordinarily, when current is supplied to an active layer with a band gap wavelength of 795 nm, due to the many-body effect of the carriers and due to the generated heat, emission components with wavelengths that are longer than that band gap wavelength can be attained, and the light emitted naturally before the laser oscillation has a wavelength of about 830 nm. Consequently, in this embodiment, when the distributed Bragg reflection wavelength of the diffraction grating layer 7 is set to 820 nm, and the band gap wavelength of the active layer 4 is set to 795 nm, the absorption loss in the active layer 4 of the phase control region 14 and the DBR region 15 is small, and laser light of 820 nm can be attained. This is because the energy levels near the band gap edge in the active layer 4 easily are saturated by absorption. Consequently, in order to decrease the absorption loss of the laser light in the active layer 4 of the phase control region 14 and the DBR region 15, it is preferable that the distributed Bragg wavelength of the diffraction grating is set to a wavelength that is at least 20 nm larger than the band gap wavelength of the active layer 4.

Configuration of the Cleaved Surfaces of the Semiconductor Laser

Light of wavelengths that are not subjected to a strong distributed Bragg reflection travels along the curved stripe-shaped window 10a on the side of the DBR region 15 and reaches the cleaved rear surface 16, where it is reflected. In this situation, the stripe-shaped window 10a defines an angle of 5° with the normal on the cleaved rear surface 16, and the laser light reflected by the cleaved rear surface 16 is reflected into a direction that is different from the stripe-shaped window 10a. FIG. 3 illustrates the proportion of light reflected at the cleaved rear surface 16 that is fed back into the waveguide (effective reflectance) as a function of the angle θ defined by the stripe-shaped window 10a and the normal on the cleaved rear surface 16. As shown in FIG. 3, when θ is set to about 5°, the proportion of the light reflected at the cleaved rear surface 16 that is fed back into the waveguide below the stripe-shaped window 10a can be suppressed to a very low level of less than 10⁻⁶. As a result, it is possible to achieve a laser oscillation with high reproducibility using only light of wavelengths that receive a strong feedback due to the distributed Bragg reflection of the diffraction grating layer 7.

Furthermore, in the structure of this embodiment, even when a large current is supplied to the gain region 13 and the phase control region 14, it is possible to achieve a laser oscillation wavelength that is selected with the DBR region 15. This is because in the structure of the present invention, even though the maximum gain is achieved near a wavelength of 805 nm, which is slightly longer than the band gap wavelength of 795 nm of the active layer 4, the waveguide intersects at an angle of 5° with the normal on the cleaved rear surface 16 as described above, so that the effective reflectance with which light is reflected at the cleaved rear surface 16 and returned into the waveguide is at a very low level of less than about 10⁻⁶, and oscillation in ordinary Fabry-Perot modes can be suppressed.

Configuration of DBR Semiconductor Laser

The contact layer 12 of the semiconductor laser of the present embodiment is partitioned into three regions with respect to the optical oscillation direction, and these three regions function as a gain region 13 for generating the laser oscillation, a phase control region 14 for controlling the phase, and a DBR region 15 in which the Bragg reflection occurs. Furthermore, by forming the diffraction grating layer 7 such that the distributed Bragg wavelength is at least 20 nm longer than the band gap wavelength, it is possible to obtain a DBR semiconductor laser with low loss and easily changeable wavelengths. Thus, it is not necessary that the band gap wavelength in the active layer 4 of the phase control region 14 and the DBR region 15 become shorter than the band gap wavelength in the active layer 4 of the gain region 13 by disordering the well layers and the barrier layers of the active layer 4 by using a technology such as diffusion of impurities or implanting of ions.

1B. Configuration of the Layers

The following is an explanation the characteristics of the various layers and the controllability of the effective refractive index difference Δn between the areas inside and outside the stripe-shaped window 10a, for the DBR semiconductor laser of the present invention.

Current Blocking Layer

Since the band gap of the Ga_{0.4}Al_{0.6}As current blocking layer 10 is larger than the band gap of the active layer 4, there is almost no absorption of laser light in the current blocking layer 10, as opposed to the related art. Consequently, the optical loss in the waveguide can be reduced considerably, and a lowering of the operation current can be achieved.

Furthermore, since hardly any optical absorption occurs in the current blocking layer 10, the optical distribution of the laser light is not limited to the portions inside the stripe-shaped window 10a, but is widened to the diffraction grating layer 7 below the current blocking layer 10. Therefore, by increasing the proportion of laser light propagating along the diffraction grating, the coupling coefficient of the diffraction grating, which determines the wavelength selectivity, can be set to a higher value. As a result, a sharp wavelength selectivity can be attained with the diffraction grating, and a single longitudinal mode can be sustained with respect to temperature changes or changes in the optical output.

Controllability of the Effective Refractive Index Difference An Regarding the Current Blocking Layer

In the present embodiment, the AlAs crystal composition ratio in the current blocking layer 10 is set to 0.6, which is higher than the AlAs crystal composition ratio in the fourth cladding layer 11, and the band gap of the current blocking layer 10 is set to be higher than the band gap of the fourth cladding layer 11. It is preferable that the band gap of the current blocking layer 10 is at least 4.8×10⁻²¹ J higher than the band gap of the fourth cladding layer 11. If the AlAs crystal composition ratio of the current blocking layer 10 were the same as that of the fourth cladding layer 11, then, due to the plasma effect when supplyding current, an anti-waveguide mode would occur due to the lower refractive index of the fourth cladding layer 11 disposed in the stripe-shaped window 10a, and it would not be possible to attain a single transverse mode oscillation. For this reason, to produce a high-power laser with stable output and high yield, it is desirable to control the effective refractive index difference Δn precisely to about 3×10⁻³ to 5×10⁻³. Here, the effective refractive index difference Δn can be controlled by the distance between the current blocking layer 10 and the active layer 4 in the gain region 13, or in other words the total thickness td of the second cladding layer 5, the first light-guiding layer 6, the second light-guiding layer 8, and the third cladding layer 9, and the difference Δx between the AlAs crystal composition ratios of the fourth cladding layer 11 and the current blocking layer 10. Here, Δx is a difference in mol content of aluminum between the fourth cladding layer 11 and the current blocking layer 10. If td is large, then the current passing through the layers between the current blocking layer 10 and the active layer 4 spreads toward the outside of the stripe-shaped window 10a, and the ineffective current that does not contribute to the laser oscillation increases. Therefore, it is preferable that that td is not too large, and an ordinary thickness is for example 0.2 μm or less. However, if td is too thin (for example less than 0.05 μm), then this ineffective current is decreased, but the effective refractive index difference Δn takes on a large value of 10⁻² or more, and the Zn serving as the p-type impurities in the fourth cladding layer 11 may diffuse into the gain region 4, deteriorating the temperature properties. Therefore, it is preferable that td is at least 0.05 μm. In the present embodiment, td is set to 0.15 μm.

Furthermore, if Δx, which is another important parameter for controlling the effective refractive index difference Δn, is large, then the influence that the reproducibility of Δx during manufacturing has on the effective refractive index difference Δn also becomes large. Consequently, it is preferable that Axis not too large. Conversely, if Δx is too small, then the optical distribution cannot be confined stably within the current supply stripe, and a stable basic transverse mode cannot be attained. Thus, it is preferable that Δx is at least 0.02 and at most 0.1. In the present embodiment, Δx is set to 0.04. By setting td and Δx within the above-noted ranges, it is possible to achieve both a decrease of the ineffective current as well as precise control of the effective refractive index difference Δn in the order of 10⁻³. In order to attain a basic transverse mode at a stable high output power, it is preferable that the effective refractive index difference Δn is set to a value between 3×10⁻³ and 5×10⁻³, and in the present embodiment, it is set to 3.5×10⁻³.

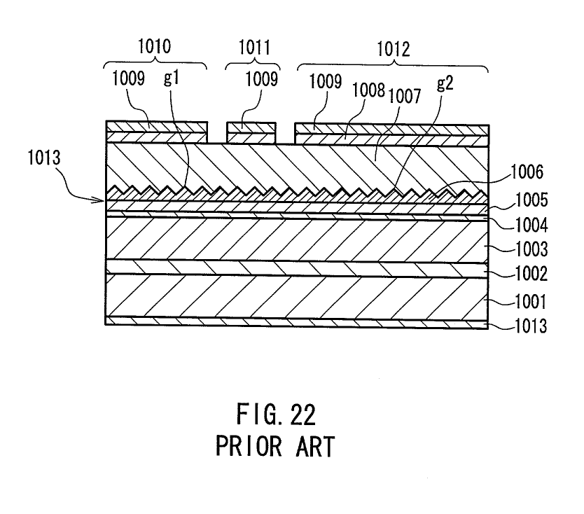

On the other hand, in the conventional structure shown in FIG. 22, a 0.25 μm thick p-type AlGaAs light-guiding layer 1006 (with an Al composition of 0.15) is formed also above the active layer 1004 in the gain region 1010. When such a thick light-guiding layer 1006 is formed above the active layer 1004 of the gain region 1010, the optical distribution of the laser light spreads broadly into the light-guiding layer 1006 with low Al crystal composition ratio, compromising the controllability of the optical distribution in the transverse direction. Actually, in conventional semiconductor lasers, an effective refractive index difference Δn between the inside and the outside the waveguide is provided in the transverse direction by a buried hetero structure, thus confining the optical distribution in the transverse direction. However, with such a buried hetero structure, the effective refractive index difference Δn becomes very large at 10⁻² or more, and the optical distribution is strongly confined in the horizontal direction. During operation at high output power, this may not only become a reason for nonlinear current—optical output characteristics caused by spatial hole burning of carriers in the active layer 1004, but it also may be a cause for an increase of the optical density at the cleaved surface 1013 due to strong confinement of light in the transverse direction, which may lead to the melt-down of the cleaved surface 1013 on the side of the gain region 1010. Therefore, it is difficult to obtain a high-power DBR semiconductor laser with the conventional structure.

Etching Controllability

It is preferable that the difference Δxg between the AlAs crystal composition ratio of the first light-guiding layer 6 and the AlAs crystal composition ratio of the diffraction grating layer 7 is as large as possible. That is to say, if the diffraction grating in the diffraction grating layer 7 is made by wet etching, and Δxg is small, then it becomes difficult to etch only the diffraction grating layer 7 selectively. The shape of the diffraction grating has a large influence on the coupling coefficient between the waveguide light and the diffraction grating, so that if the diffraction grating in the diffraction grating layer 7 is made by wet etching, then it is very important to control the shape of the diffraction grating. Consequently, rather than controlling the shape of the diffraction grating through the etching time, the shape controllability of the diffraction grating is larger if the shape of the diffraction grating is controlled with a selective etching process, in which the etching stops as soon as the first light-guiding layer 6 below the diffraction grating layer 7 is exposed. Thus, to increase the selective etching properties, it is desirable that Δxg is fairly large, and more specifically, it is desirable that it is at least 0.05.

First Light-Guiding Layer

On the other hand, it is desirable that the AlAs crystal composition ratio of the first light-guiding layer 6 is as small as possible. The reason for that is as follows. In the gain region 13, the second light-guiding layer 8 is arranged directly on the first light-guiding layer 6, so that it is formed by regrowing the crystal on the first light-guiding layer 6. If the AlAs crystal composition ratio of the first light-guiding layer 6 is large, then the crystal regrowth interface oxidizes easily during the crystal regrowth. Such oxidation of the interface may cause an increase in the electrical resistance of the semiconductor laser. Consequently, it is desirable that the AlAs crystal composition ratio of the first light-guiding layer 6 is set to a small value, so that the interface hardly oxidizes in the crystal regrowth step. In the present embodiment, the AlAs crystal composition ratio of the first light-guiding layer 6 is 0.3. This makes it possible to prevent an increase of the resistance of the regrowth interface in the gain region 13 due to the crystal regrowth. Furthermore, it is desirable that the thickness of the first light-guiding layer 6 is as small as possible, so that it has almost no influence on the optical distribution in the transverse direction. In the present embodiment, the thickness of the first light-guiding layer 6 is set to 10 nm. Thus, by using a first light-guiding layer 6 whose AlAs crystal composition ratio is small and whose thickness is thin, it is possible to attain a regrowth interface of low resistance, without harming the controllability of the effective refractive index difference Δn.

Third Cladding Layer

Similarly, it is also desirable that the AlAs crystal composition ratio of the third cladding layer 9 is as small as possible. This is because the fourth cladding layer 11 in the stripe-shaped window 10a is regrown on the third cladding layer 9, so that if the AlAs crystal composition ratio of the third cladding layer 9 is large, the crystal regrowth interface is susceptible to oxidation, and such oxidation of the interface may cause an increase in the electrical resistance of the semiconductor laser. Furthermore, it is desirable that the AlAs crystal composition ratio of the third cladding layer 9 is at most 0.3, because then the etching selectivity with respect the Ga_{0.4}Al_{0.6}As current blocking layer 10 is high, the crystal regrowth on it becomes easy, and light of the laser oscillation wavelength is not absorbed. In the present embodiment, the AlAs crystal composition ratio of the third cladding layer is set to 0.2. Thus, it is possible to prevent an increase of the crystal regrowth interface. Furthermore, it is desirable that the third cladding layer 9 is as thin as possible, so that it has almost no influence on the optical distribution in the transverse direction. In the present embodiment, the thickness of the third cladding layer 9 is set to 10 nm. Thus, by making the AlAs crystal composition ratio small and using a thin third cladding layer 9, it is possible to achieve a regrowth interface with low resistance, without harming the controllability of the effective refractive index difference Δn.

Diffraction Grating Layer

In view of high power operation, precise control of the effective refractive index difference Δn in the DBR region 15 in the order of 10⁻³ is necessary, and it is also preferable that the diffraction grating layer 7 is as thin as possible, so that it has almost no influence on the optical distribution in the transverse direction. However, if it is too thin, the coupling coefficient between the guided light and the diffraction grating becomes small, and the reflectance of the laser light in the DBR region 15 becomes small. Consequently, it is preferable that the thickness of the diffraction grating layer 7 is set to at least 5 nm and at most 60 nm. In the present embodiment, the thickness of the diffraction grating layer 7 is set to 20 nm.

Thus, the structure of the DBR semiconductor laser of the present embodiment is such that effective refractive index difference Δn can be controlled precisely in the order of 10⁻³ in all regions, that is, in the gain region 13, the phase control region 14 as well as the DBR region 15, making it possible to achieve a stable single transverse mode oscillation at high output power.

Second Cladding Layer

It is preferable the AsAs crystal composition ratio of the second cladding layer 5 is sufficiently higher than that of the active layer 4, such that the band gap of the second cladding layer 5 is sufficiently larger than the band gap of the active layer 4. Thus, it is possible to confine carriers in the active layer 4 effectively. For example, to attain a laser oscillation in the 820 nm band, an AlAs crystal composition ratio of at least about 0.45 is desirable. In this embodiment, the AlAs crystal composition ratio of the second cladding layer 5 is 0.5.

Width of the Stripe-Shaped Window

In order to reduce the maximum optical density at the cleaved front surface 17 on the side of the gain region 13 to prevent the melt-down of the cleaved front surface 17, the width W of the stripe-shaped window 10a should be as broad as possible within the range in which the basic transverse mode can be attained. However, if it is too broad, then oscillation of transverse modes of higher harmonics may become possible, so that it is preferable that it is not too broad. Consequently, it is preferable that W is at least 2 μm and at most 5 μm. In the present embodiment, the width of the stripe-shaped window 10a is set to 3.5 μm.

Wavelength Selectivity

In the semiconductor laser of the present embodiment, the period of the diffraction grating formed in the diffraction grating layer 7 is an integer multiple of the medium-intrinsic wavelength. The wavelength of the laser light guided along the optical waveguide is selected by the Bragg reflection at the diffraction grating. The refractive index difference between the diffraction grating layer 7 and the second light-guiding layer 8 above it determines the wavelength selectivity due to the diffraction grating. It is desirable that the AlAs crystal composition ratio of the diffraction grating layer 7 is set to not more than 0.3 nm, so as to achieve a favorable wavelength selectivity and to facilitate the crystal regrowth on it, and also such that light of the laser oscillation wavelength is not absorbed. In the present embodiment, the AlAs crystal composition ratio of the diffraction grating layer 7 is 0.2. On the other hand, it is desirable that the AlAs crystal composition ratio of the second light-guiding layer 8 is at least 0.5m, so that a sufficient refractive index difference to the diffraction grating layer 7 can be achieved, which is necessary for a single longitudinal mode. In the present embodiment, the AlAs crystal composition ratio of the second light-guiding layer 8 is 0.5.

1C. Steps for Manufacturing the DBR Semiconductor Laser

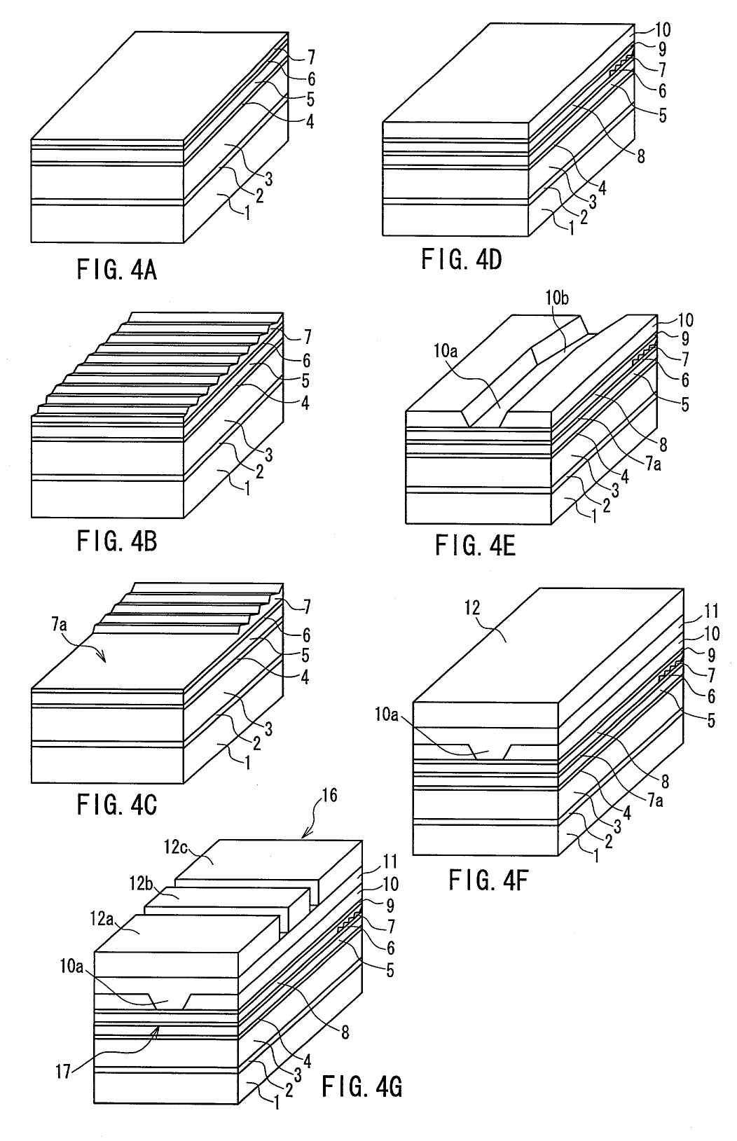

FIGS. 4A to 4G are perspective views of the steps for manufacturing the DBR semiconductor laser according to the present embodiment.

As shown in FIG. 4A, in a first crystal growth step with MOCVD or MBE, the n-type GaAs buffer layer 2 (0.5 μm thickness), the n-type Ga_{0.5}Al_{0.5}As first cladding layer 3 (1 μm thickness), the active layer 4 of multiple quantum wells of Ga_{0.7}Al_{0.3}As barrier layers and GaAs well layers, the p-type Ga_{0.5}Al_{0.5}As second cladding layer 5 (0.08 μm thickness), the p-type Ga_{0.7}Al_{0.3}As first light-guiding layer 6 (0.01 μm thickness), and the p-type Ga_{0.8}Al_{0.2}As diffraction grating layer 7 (0.02 μm thickness) are layered on the n-type GaAs substrate 1.

The active layer 4 uses unstrained multiple quantum wells in the present embodiment, but it is also possible to use strained quantum wells or a bulk active layer. Furthermore, there is no particular limitation regarding the conductivity type of the active layer 4, and it can be p-type, n-type or undoped.

Here, the diffraction grating layer 7 is formed above the active layer 4, so that the crystallinity of the active layer 4 is not decreased due to the crystal regrowth, and a production at high yield is possible.

Next, as shown in FIG. 4B, a diffraction grating having a certain period in the optical resonance direction is formed in the diffraction grating layer 7 by interference exposure, electron beam exposure or the like and wet etching or dry etching.

Next, as shown in FIG. 4C, a portion of the diffraction grating layer 7 is removed by wet etching or dry etching, forming the diffraction grating layer non-formation region 7a. This diffraction grating layer non-formation region 7a serves as the gain region 13 and the phase control region 14, and the region where the diffraction grating layer 7 has not been removed (diffraction grating layer formation region) serves as the DBR region 15.

Next, in a second crystal growth step, the p-type Ga_{0.5}Al_{0.5}As second light guiding layer 8 (0.05 μm thickness), the p-type Ga_{0.8}Al_{0.2}As third cladding layer 9 (0.01 μm thickness), and the n-type Ga_{0.4}Al_{0.6}As current blocking layer 10 (0.6 μm thickness) are formed on the diffraction grating layer 7 and the first light-guiding layer 6 in the diffraction grating layer non-formation region, as shown in FIG. 4D. It should be noted that when the current blocking layer 10 is thin, the confinement of the light in the transverse direction may be insufficient, and the transverse mode may become unstable, so that it is desirable that the thickness of the current blocking layer 10 is at least 0.4 μm.

Subsequently, the stripe-shaped window 10a for current constriction is formed by etching in the Ga_{0.4}Al_{0.6}As current blocking layer 10, as shown in FIG. 4E. During the etching, the stripe-shaped window 10a is etched with a bend near the cleaved rear surface 16, so that the waveguide forms a 5° angle with the normal on the cleaved rear surface 16 on the side of the cleaved rear surface 16. This makes it possible to lower the effective reflectance at the cleaved rear surface 16 to a level of less than 10⁻⁶. The width W of the stripe-shaped window 10a was set to 3.5 μm in order to widen the optical distribution as much as possible in the transverse direction. During the etching, it is possible to stop the etching at the Ga_{0.8}Al_{0.2}As third cladding layer 9 by using an etchant such as hydrofluoric acid, which selectively etches layers with high AlAs crystal composition ratio. Thus, a semiconductor laser suitable for mass production can be attained without irregularities in its characteristics due to etching irregularities and with high yield.

For the groove shape of the stripe-shaped window 10a, a regular mesa shape is preferable to an inverted mesa shape. This is because with an inverted mesa shape, the fill-up-type crystal growth on top of the inverted mesa shape is more difficult than for a regular mesa shape, which may lead to a decrease in the yield caused by a decrease in properties.

Next, in a third crystal growth step, on the current blocking layer 10 including the stripe-shaped window 10a, the p-type Ga_{0.44}Al_{0.56}As fourth cladding layer 11 (2 μm thickness) and the p-type GaAs contact layer 12 (2 μm thickness) are formed, as shown in FIG. 4F. With this structure, it is possible to achieve an effective refractive index difference Δn of 3.5×10⁻³ between inside and outside the stripe-shaped window 10a. Thus, it is possible to confine the optical distribution stably within the stripe-shaped window 10a with a width W of 3.5 μm even during high-power output, and it becomes possible to achieve a stable basic transverse mode oscillation up to high-power outputs.

Then, a contact layer 12 partitioned into three regions, namely the contact layers 12a to 12c for the gain region 13, the phase control region 14 and the DBR region 15, is formed by wet etching or by dry etching, as shown in FIG. 4G.

Lastly, the cleaved front surface 17 from which the laser light is emitted is provided with a coating with low reflectance of 3%, so as to allow high-power operation. On the side of the cleaved rear surface 16, the waveguide is tilted with respect to the normal on the cleaved rear surface 16, so that the reflectance at the cleaved rear surface 16 is effectively set to a very low value of less than 10⁻⁶, but in order to prevent reflection reliably at the cleaved rear surface 16, it is desirable that the cleaved rear surface 16 is provided with a non-reflectance coating of not more than 1% reflectance. Thus, the longitudinal mode control in the diffraction grating can be carried out even more reliably.

Second Embodiment

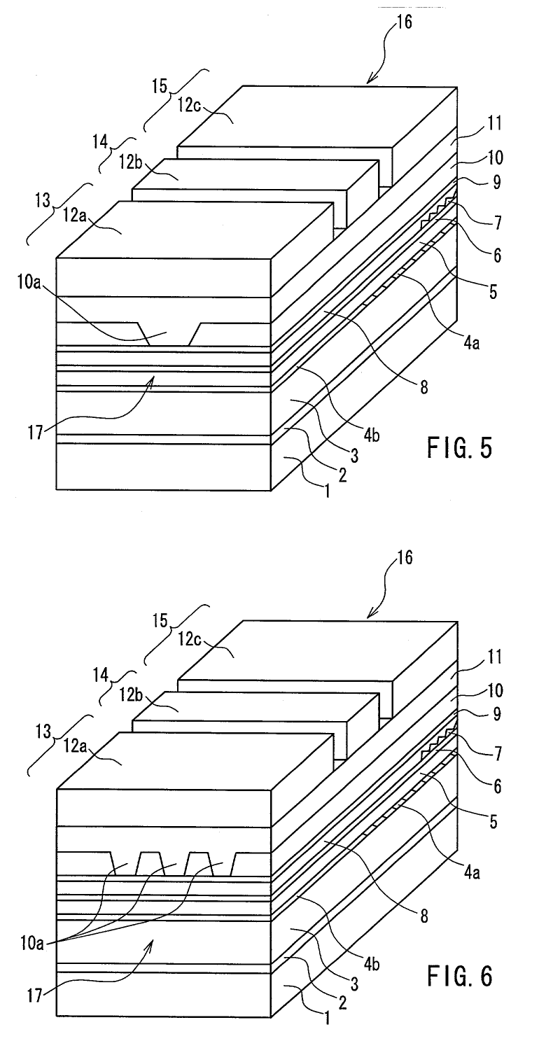

FIG. 5 is a perspective view of a DBR semiconductor laser incorporating a diffraction grating within a waveguide in accordance with a second embodiment of the present invention. In this DBR semiconductor laser, the active layer of multiple quantum wells of Ga_{0.7}Al_{0.3}As barrier layers and GaAs well layers is different regarding the phase control region 14, the DBR region 15 and the gain region 13, but other aspects of the configuration are analogous to the DBR semiconductor laser described in the first embodiment.

The following is an explanation of the active layer in the DBR semiconductor laser of the present embodiment.

The active layer 4a of the DBR region 15 and the phase control region 14 is disordered by ion implantation or diffusion of impurities, and its band gap is larger than the band gap of the active layer 4b in the gain region 13. Consequently, the laser light emitted in the gain region 13 is not absorbed by the active layer 4a in the DBR region 15 and the phase control region 14, so that an effect is attained in which the emission efficiency of the DBR semiconductor laser as well as the coupling efficiency between the diffraction grating and the laser light are both improved. Furthermore, in this situation, it is desirable that the band gap wavelength corresponding to the band gap of the active layer 4a in the DBR region 15 and the phase control region 14 is as short as possible, so that the light emitted when current is supplied into the DBR region 15 or the phase control region 14 has no influence on the optical characteristics of the gain region 13. However, when this band gap wavelength is made too short, then the waveguide losses in the DBR region 15 and the phase control region 14 become large. Consequently, it is necessary that the wavelength is not made too short. More specifically, it is desirable that the active layer 4a is disordered, such that its band gap wavelength is at least 10 nm and at most 80 nm shorter than the band gap wavelength of the active layer 4b in the gain region 13. In this embodiment, the active layer 4a of the DBR region 15 and the phase control region is disordered, so that the band gap wavelength of the DBR region 15 and the phase control region 14 is short at 15 nm. Thus, the wavelength loss in the DBR region 15 and the phase control region 16 becomes less than 20 cm⁻¹.

In this structure, the current supplied from the p-type GaAs contact layer 12a is confined by the n-type Ga_{0.4}Al_{0.6}As current blocking layer 10 to within the stripe-shaped window 10a, and the optical emission occurs in the active layer 4b below the p-type GaAs contact layer 12a. The generated light is subjected to a distributed Bragg reflection by the diffraction grating layer 7, and as a result of the wavelength selection, a single longitudinal mode oscillation is achieved. By changing the value of the current supplied to the DBR region 15 and the phase control region 14, the laser oscillation wavelength sustains and controls a single longitudinal mode oscillation.

It should be noted that the semiconductor laser of the present embodiment, can be produced by adding a step of disordering the active layer 4a to the manufacturing steps of the semiconductor laser explained for the first embodiment.

Third Embodiment

FIG. 6 is a perspective view of a DBR semiconductor laser incorporating a diffraction grating within a waveguide in accordance with a third embodiment of the present invention. This DBR semiconductor laser is provided with a plurality (three in FIG. 6) of stripe-shaped windows 10a in the current blocking layer 10, but other configurational aspects are analogous to the DBR semiconductor laser explained in the first embodiment.

The following is an explanation of the plurality of stripe-shaped windows 10a provided in the DBR semiconductor laser of this embodiment.

In this DBR semiconductor laser, the current supplied from the p-type GaAs contact layer 12a is confined by the n-type Ga_{0.4}Al_{0.6}As current blocking layer 10 within the plurality of stripe-shaped windows 10a, and the optical emission occurs in the active layer 4 below the p-type GaAs contact layer 12. The generated light is subjected to a distributed Bragg reflection by the diffraction grating layer 7, and as a result of the wavelength selection, a single longitudinal mode oscillation is achieved.

Here, the band gap of the Ga_{0.4}Al_{0.6}As current blocking layer 10 is larger than the band gap of the active layer 4 of multiple quantum wells of Ga_{0.7}Al_{0.3}As barrier layers and GaAs well layers, so that absorption of the laser light by the current blocking layer as in the conventional structure can be inhibited. Consequently, the loss in the waveguide can be reduced considerably, and lower currents can be used during operation. Furthermore, the optical distribution below the plurality of stripe-shaped windows 10a tends to widen in the transverse direction, because the current blocking layer 10a is transparent for the laser light. Consequently, the optical distributions interfere with one another and phase synchronization is achieved, if the stripe-shaped windows 10a are brought close enough to one another that the distance between neighboring stripe-shaped windows 10a is small enough that the optical distributions extending into the regions outside the windows 10a overlap with one another. In particular, if the stripe-shaped window 10a in the middle is made narrower than the other stripe-shaped windows 10a in order to maximize the gain in the active layer 4 directly below the stripe-shaped window 10a in the middle, a basic transverse mode oscillation at a phase difference of 0₀ can be attained in the case of phase synchronization. More specifically, in this embodiment, the width of the middle stripe-shaped window 10a is 4 μm, the width of the two outer stripe-shaped windows is 5 μm, and the spacing between the neighboring stripe-shaped windows 10a is 4 μm. The spacing between the neighboring stripe-shaped windows 10a should be within a distance at which the optical distributions interfere with one another, and it is desirable that it is not greater than 5 μm. With phase synchronization at a phase difference of 0₀, it is possible to attain a basic transverse mode oscillation with a uni-modal far-field image, and a large-power output of at least 1 W can be achieved.

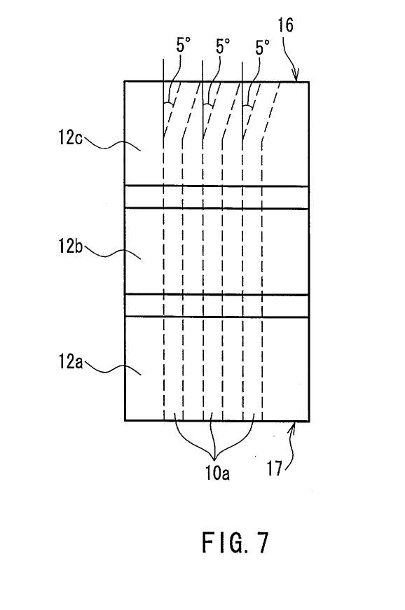

As shown in FIG. 7, the plurality of stripe-shaped windows 10a forming the waveguide intersect with the cleaved rear surface 16 at an angle of 5° with respect to the normal on the cleaved rear surface 16. That is to say, the stripe-shaped windows 10a are bent near the cleaved rear surface 16 at an angle of 5° against the normal on the cleaved rear surface 16 within a plane that is parallel to the active layer 4. Here, the length of the bent part of the stripe-shaped windows 10a is 300 μm each.

Light of wavelengths that are not subjected to a strong distributed Bragg reflection reaches the region where the stripe-shaped windows 10a are bent, and is reflected by the cleaved rear surface 16. In this situation, the plurality of stripe-shaped windows 10a form an angle of 50 with the normal on the cleaved rear surface 16, the laser light reflected by the cleaved rear surface 16 is reflected in a direction that is different from the stripe-shaped windows 10a, and a reflectance of less than 10⁻⁶ can be attained. As a result, it is possible to achieve a laser oscillation with high reproducibility using only light of wavelengths that receive a strong feedback due to the distributed Bragg reflection of the diffraction grating layer 7.

Thus, with this DBR semiconductor laser including a plurality of stripe-shaped windows 10a, it is possible to attain a large-power output of at least 1 W, in addition to the effects achieved by the DBR semiconductor laser described in the first embodiment.

The manufacturing steps for the DBR semiconductor laser of this embodiment are the same as the manufacturing steps of the DBR semiconductor laser described for the first embodiment, except for the formation of the plurality of parallel stripe-shaped windows 10a.

Fourth Embodiment

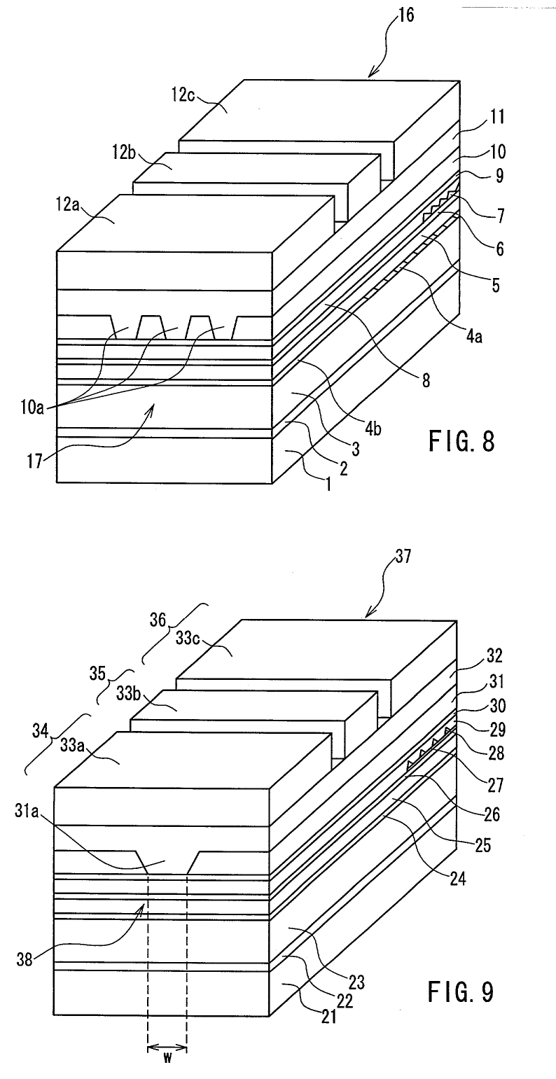

FIG. 8 is a perspective view of a DBR semiconductor laser incorporating a diffraction grating within a waveguide in accordance with a fourth embodiment of the present invention. This DBR semiconductor laser has the same configuration as the DBR semiconductor laser explained in the first embodiment, except that in this DBR semiconductor laser, in the active layer of multiple quantum wells of Ga_{0.7}Al_{0.3}As barrier layers and GaAs well layers, the active layer 4a in the phase control region 14 and the DBR region is disordered, whereas the active layer 4b in the gain region 13 is not disordered, and a plurality of stripe-shaped windows 10a are provided.

The providing of a disordered active layer 4a in the phase control region 14 and the DBR region 15 and an active layer 4b that is not disordered in the gain region 13, as well as the providing of the plurality of stripe-shaped windows 10a are explained in the second and the third embodiments.

Fifth Embodiment

FIG. 9 is a perspective view of a DBR semiconductor laser incorporating a diffraction grating within a waveguide in accordance with a fourth embodiment of the present invention. This DBR semiconductor laser is partitioned into three regions in the optical resonance direction, and includes a gain region 34, a phase control region 34 and a DBR region. In this structure, a resonator is formed by a cleaved front surface 38 near the gain region 13 and a DBR due to the diffraction grating in the DBR region 36, which serve as the two reflection mirrors, and guided light is amplified in the gain region 34, thus achieving laser oscillation. The following is an explanation of the layering structure of this semiconductor laser. An n-type GaAs buffer layer 22, an n-type Ga_{0.5}Al_{0.5}As first cladding layer 23, an active layer 24 of multiple quantum wells of Ga_{0.7}Al_{0.3}As barrier layers and GaAs well layers, a p-type Ga_{0.5}Al_{0.5}As second cladding layer (first semiconductor layer) 25, and a p-type Ga_{0.7}Al_{0.3}As first light-guiding layer (third semiconductor layer) 26 are layered on an n-type GaAs substrate 21. Furthermore, a p-type Ga_{0.4}Al_{0.6}As second cladding layer (fifth semiconductor layer) 27 and a p-type Ga_{0.8}Al_{0.2}As diffraction grating layer (second semiconductor layer) 28 for subjecting the guided light to distributed Bragg reflection are provided on top of the first light-guiding layer 26. The difference between the AlAs crystal composition ratios of the second light-guiding layer 27 and the diffraction grating layer 28 is set to be larger than the difference between the AlAs crystal composition ratios of the first light-guiding layer 26 and the diffraction grating layer 28. That is to say, the selective etching ratio between the second light-guiding layer 27 and the diffraction grating layer 28 is larger than the selective etching ratio between the first light-guiding layer 26 and the diffraction grating layer 28. The second cladding layer 27 and the diffraction grating layer 28 diffraction grating layer 7 are provided only in the DBR region 36, and not in the gain region 34 or in the phase control region 35. This means that on the first light-guiding layer 26, there is a diffraction grating layer formation region in which the second light-guiding layer 27 and the diffraction grating layer 28 are formed, and a diffraction grating layer non-formation region in which the second light-guiding layer 27 and the diffraction grating layer 28 are not formed. A p-type Ga_{0.5}Al_{0.5}As third light guiding layer 29 and a p-type Ga_{0.8}Al_{0.2}As third cladding layer 30 are provided on the diffraction grating layer 28 (and also on the diffraction grating layer non-formation region). On top of that, an n-type Ga_{0.4}Al_{0.6}As current blocking layer 31 for current constriction provided with a stripe-shaped window 31a is provided. Furthermore, a p-type Ga_{0.44}Al_{0.56}As fourth cladding layer (fourth semiconductor layer) 32 as well as p-type GaAs contact layers 33a to 33c partitioned into three with respect to the optical resonance direction are provided on top of the current blocking layer 31 including the stripe-shaped window 31a. The p-type GaAs contact layers 33a and 33b partition the diffraction grating layer non-formation region into two regions with respect to the optical resonance direction whereas the p-type GaAs contact layer 33c is provided on the diffraction, grating layer formation region. In this embodiment, the diffraction grating layer 28 is provided only in the DBR region 36 and not in the gain region 34 and the phase control region 35, but it is sufficient if the diffraction grating layer 28 is arranged such that it has no influence on the optical distribution in the gain region 34. Consequently, the diffraction layer 28 should be arranged in a region that is at least outside the region opposite the optical waveguide of the active layer 24 in the gain region 34 (region in which current is supplied). Furthermore, the DBR region 36 should be provided with a diffraction grating, so that the diffraction grating 28 should be provided at least in the DBR region 36.

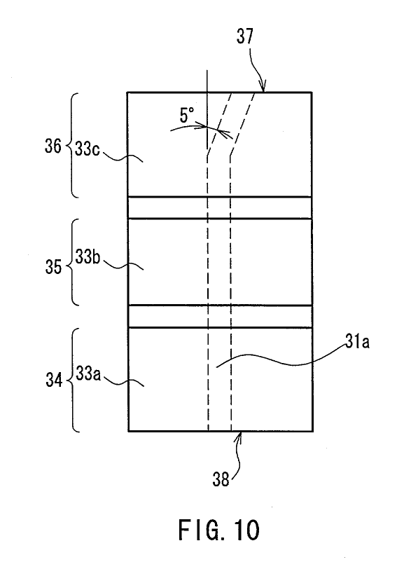

Furthermore, as shown in FIG. 10, the stripe-shaped window 31a for forming the waveguide intersects with the cleaved rear surface 37 at an angle of 5° with respect to the normal on the cleaved rear surface 37 on the side of the DBR region in the semiconductor laser. That is to say, the current blocking layer 31 is provided with a stripe-shaped window 31a that is bent midway at an angle of 5° with respect to the normal on the cleaved rear surface 37 within a plane that is parallel to the active layer 24. The bent part of the stripe-shaped window 31a has a length of 300 μm. The angle defined by the stripe-shaped window 31a and the normal on the cleaved rear surface 37 is preferably at least 1° and at most 100. The length of the bent part of the stripe-shaped window 31a is preferably at least 100 μm.

With this structure, current supplied from the p-type GaAs contact layer 33a of the gain region 34 reaches the active layer 24 below the p-type GaAs contact layer 33a after being constricted to the stripe-shaped window 31a by the n-type Ga_{0.4}Al_{0.6}As current blocking layer 31, and an emission occurs in the stripe-shaped region of the active layer 24, into which current has been supplied (i.e. in the current supply stripe of the active layer 24). As a result of being subjected to wavelength selection due to the distributed Bragg reflection by the diffraction grating layer 28, the generated light oscillates in a single longitudinal mode.

The following is an explanation of the characteristics of this DBR semiconductor laser, broken down into its structural parts.

5A. Configuration in Waveguide Direction

DBR Region

To use DBR semiconductor lasers as SHG excitation light sources, it is necessary to control the laser oscillation wavelength such that a high second harmonic conversion efficiency can be attained with the non-linear optical element used for SHG. The wavelength of the distributed Bragg reflected wave can be controlled with the amount of current supplied to the GaAs contact layer 33c. This is because if the current supply is carried out mainly at the GaAs contact layer 33c, then it is possible to alter the spacing of the diffraction grating formed in the diffraction grating layer 28 by the generation of heat. This means, to change the wavelength of the laser oscillation toward longer wavelengths, the current supplied to the GaAs contact layer 12c should be increased, whereas to change the wavelength of the laser oscillation toward shorter wavelengths, the current supplied to the GaAs contact layer 33c should be decreased.

Here, if the length of the DBR region 15 in the optical resonance direction is long, then a high reflectance can be attained because of the increased coupling between the diffraction grating and the guided optical wave, but if it is too long, then the dissipated heat increases, and the variability of the oscillation wavelength by heat generation is harmed. Consequently, it is preferable that the length of the DBR region is set to at least 100 μm and at most 700 μm. In the DBR semiconductor laser according to this embodiment, the length of the DBR region is set to 300 μm. In this embodiment, by changing the value of the current supplied to the GaAs contact layer 33c for example between 0 mA and 100 mA, the oscillation wavelength can be tuned in a range of about 3 nm.

Phase Control Region

When changing the distributed Bragg wavelength, there may be two or more wavelengths for which a high reflectance can be attained near the desired laser oscillation wavelength. In this situation, mode-hopping to the wavelength with the higher gain may occur, and there is the possibility that the laser oscillation wavelength deviates from the desired oscillation wavelength. To prevent this, the value of the current supplied to the GaAs contact layer 33b in the phase control region 35 is changed, the effective length of the waveguide below the GaAs contact layer 33b is changed by heat generation, and controlled such that the phase condition for laser oscillation is satisfied only by the desired oscillation wavelength. Here, when the phase control region 35 is long with respect to the optical resonance direction, then the dissipated heat increases, and the variability of the oscillation wavelength by heat generation is harmed. Conversely, if the phase control region 35 is short, then the change of the effective waveguide length caused by the heat generation may be too small. Consequently, it is preferable that the length of the phase control region 35 is at least 100μm and at most 700 μm. In the present embodiment, the length of the phase control region 35 is set to 250 μm.

Configuration of the Diffraction Grating

Ordinarily, when current is supplied to an active layer with a band gap wavelength of 795 nm, due to the many-body effect of the carriers and due to the generated heat, emission components with wavelengths that are longer than that band gap wavelength can be attained, and the light emitted naturally before the laser oscillation has a wavelength of about 830 nm. Consequently, in this embodiment, when the distributed Bragg reflection wavelength of the diffraction grating layer 28 is set to 820 nm, and the band gap wavelength of the active layer 24 is set to 795 nm, the absorption loss in the active layer 24 of the phase control region 35 and the DBR region 36 is small, and laser light of 820 nm can be attained. This is, because the energy levels near the band gap edge in the active layer 24 easily are saturated by absorption. Consequently, in order to decrease the absorption loss of the laser light in the active layer 24 of the phase control region 35 and the DBR region 36, it is preferable that the distributed Bragg wavelength of the diffraction grating is set to a wavelength that is at least 20 nm larger than the band gap wavelength of the active layer 24.

Configuration of the Cleaved Surfaces of the Semiconductor Laser

Light of wavelengths that are not subjected to a strong distributed Bragg reflection travels along the curved stripe-shaped window 31a on the side of the DBR region and reaches the cleaved rear surface 37, where it is reflected. In this situation, the stripe-shaped window 31a defines an angle of 5° with the normal on the cleaved rear surface 37, and the laser light reflected by the cleaved rear surface 37 is reflected into a direction that is different from the stripe-shaped window 31a. More specifically, as shown in FIG. 3, the proportion of the light reflected at the cleaved rear surface 37 that is fed back into the waveguide below the stripe-shaped window 31a can be suppressed to a very low level of less than 10⁻⁶. As a result, it is possible to achieve a laser oscillation with high reproducibility using only light of wavelengths that receive a strong feedback due to the distributed Bragg reflection of the diffraction grating layer 28.

Furthermore, in the structure of this embodiment, even when a large current is supplied to the gain region 34 and the phase control region 35, it is possible to achieve a laser oscillation wavelength that is selected with the DBR region 36. This is because in the structure of the present invention, even though the maximum gain is achieved near a wavelength of 805 nm, which is slightly longer than the band gap wavelength of 795 nm of the active layer 24, the waveguide intersects at an angle of 5° with the normal on the cleaved rear surface 37 as described above, so that the effective reflectance with which light is reflected at the cleaved rear surface 37 and returned into the waveguide is at a very low level of less than about 10⁻⁶, and oscillation in ordinary Fabry-Perot modes can be suppressed.

Configuration of DBR Semiconductor Laser

The contact layer 33 of the semiconductor laser of the present embodiment is partitioned into three regions with respect to the optical resonanse direction, and these three regions function as a gain region 34 for generating the laser oscillation, a phase control region 35 for controlling the phase, and a DBR region 36 in which the Bragg reflection occurs.

Furthermore, by forming the diffraction grating layer 28 such that the distributed Bragg wavelength is at least 20 nm longer than the band gap wavelength, it is possible to obtain a DBR semiconductor laser with low loss and easily changeable wavelengths, in which the band gap wavelength in the active layer 24 of the phase control region 35 and the DBR region 36 does not become shorter than the band gap wavelength in the active layer 24 of the gain region 34 by disordering the well layers and the barrier layers of the gain region 4 by using a technology such as diffusion of impurities or implanting of ions.

1B. Configuration of the Layers

The following is an explanation the characteristics of the various layers and the controllability of the effective refractive index difference Δn between the areas inside and outside the stripe-shaped window 31a, for the DBR semiconductor laser of the present invention.

Current Blocking Layer

Since the band gap of the Ga_{0.4}Al_{0.6}As current blocking layer 31 is larger than the band gap of the active layer 24, there is almost no absorption of laser light in the current blocking layer 31, as opposed to the related art. Consequently, the optical loss in the waveguide can be reduced considerably, and a lowering of the operation current can be achieved.

Furthermore, since hardly any optical absorption occurs in the current blocking layer 31, the optical distribution of the laser light is not limited to the portions inside the stripe-shaped window 31a, but is widened to the diffraction grating layer 28 below the current blocking layer 31. Therefore, by increasing the proportion of laser light propagating along the diffraction grating, the coupling coefficient of the diffraction grating, which determines the wavelength selectivity, can be set to a higher value. As a result, a sharp wavelength selectivity can be attained with the diffraction grating, and a single longitudinal mode can be sustained with respect to temperature changes or changes in the optical output.

Controllability of the Effective Refractive Index Difference Δn Regarding the Current Blocking Layer

In the present embodiment, the AlAs crystal composition ratio in the current blocking layer 31 is set to 0.6, which is higher than the AlAs crystal composition ratio in the fourth cladding layer 32, and the band gap of the current blocking layer 31 is set to be higher than the band gap of the fourth cladding layer 32. It is preferable that the band gap of the current blocking layer 31 is at least 4.8 ×10⁻²¹ J higher than the band gap of the fourth cladding layer 32. If the AlAs crystal composition ratio of the current blocking layer 31 were the same as that of the fourth cladding layer 32, then, due to the plasma effect when supplyding current, an anti-waveguide mode would occur due to the lower refractive index of the fourth cladding layer 32 disposed in the stripe-shaped window 31a, and it would not be possible to attain a single transverse mode oscillation. For this reason, to produce a high-power laser with stable output and high yield, it is desirable to control the effective refractive index difference Δn precisely to about 3×10⁻³ to 5×10⁻³. Here, the effective refractive index difference Δn can be controlled by the distance between the current blocking layer 31 and the active layer 24 in the gain region 34, or in other words the total thickness td2 of the second cladding layer 25, the first light-guiding layer 26, the second light-guiding layer 27, the third light-guiding layer 29 and the third cladding layer 30, and the difference Δx2 between the AlAs crystal composition ratios of the fourth cladding layer 32 and the current blocking layer 31. Here, Δx2 is a difference in mol content of aluminum between the fourth cladding layer 32 and the current blocking layer 31. If td2 is large, then the current passing through the layers between the current blocking layer 31 and the active layer 24 spreads toward the outside of the stripe-shaped window 31a, and the ineffective current that does not contribute to the laser oscillation increases. Therefore, it is preferable that that td2 is not too large, and an ordinary thickness is for example 0.2 μm or less. However, if td2 is too thin (for example less than 0.05 μm), then this ineffective current is decreased, but the effective refractive index difference Δn takes on a large value of 10⁻² or more, and the Zn serving as the p-type impurities in the fourth cladding layer 32 may diffuse into the gain region 24, deteriorating the temperature properties. Therefore, it is preferable that td is at least 0.05 μm. In the present embodiment, td is set to 0.15 μm.

Furthermore, if Δx2, which is another important parameter for controlling the effective refractive index difference Δn, is large, then the influence that the reproducibility of Δx2 during manufacturing has on the effective refractive index difference Δn also becomes large. Consequently, it is preferable that Δx2 is not too large. Conversely, if Δx2 is too small, then the optical distribution cannot be confined stably within the current supply stripe, and a stable basic transverse mode cannot be attained. Thus, it is preferable that Δx2 is at least 0.02 and at most 0.1. In the present embodiment, Δx2 is set to 0.04. By setting td2 and Δx2 within the above-noted ranges, it is possible to achieve both a decrease of the ineffective current as well as precise control of the effective refractive index difference Δn in the order of 10⁻³. In order to attain a basic transverse mode at a stable high output power, it is preferable that the effective refractive index difference Δn is set to a value between 3×10⁻³ and 5×10⁻³, and in the present embodiment, it is set to 3.5×10⁻³.

On the other hand, in the conventional structure shown in FIG. 22, a 0.25 μm thick p-type AlGaAs light-guiding layer 1006 (with an Al composition of 0.15) is formed also above the active layer 1004 in the gain region 1010. When such a thick light-guiding layer 1006 is formed above the active layer 1004 of the gain region 1010, the optical distribution of the laser light spreads broadly into the light-guiding layer 1006 with low Al crystal composition ratio, compromising the controllability of the optical distribution in the transverse direction. Actually, in conventional semiconductor lasers, an effective refractive index difference Δn between the inside and the outside of the waveguide is provided in the transverse direction by a buried hetero structure, thus confining the optical distribution in the transverse direction. However, with such a buried hetero structure, the effective refractive index difference Δn becomes very large at 10⁻² or more, and the optical distribution is strongly confined in the horizontal direction. During operation at high output power, this may not only become a reason for nonlinear current—optical output characteristics caused by spatial hole burning of carriers in the active layer 1004, but it also may be a cause for an increase of the optical density at the cleaved surface 1013 due to strong confinement of light in the transverse direction, which may lead to the melt-down of the cleaved surface 1013 on the side of the gain region 1010. Therefore, it is difficult to realize a high-power DBR semiconductor laser with the conventional structure.

Etching Controllability

It is preferable that the difference Δxg2 between the AlAs crystal composition ratio of the second light-guiding layer 27 and the AlAs crystal composition ratio of the diffraction grating layer 28 is as large as possible. That is to say, if the diffraction grating in the diffraction grating layer 28 is made by wet etching, and Δxg2 is small, then it becomes difficult to etch only the diffraction grating layer 28 selectively. The shape of the diffraction grating has a large influence on the coupling coefficient between the waveguide light and the diffraction grating, so that if the diffraction grating in the diffraction grating layer 28 is made by wet etching, then it is very important to control the shape of the diffraction grating. Consequently, rather than controlling the shape of the diffraction grating through the etching time, the shape controllability of the diffraction grating is larger if the shape of the diffraction grating is controlled with a selective etching process, in which the etching stops as soon as the first light-guiding layer 26 below the diffraction grating layer 28 is exposed. Thus, to increase the selective etching properties, it is desirable that Δxg2 is fairly large, and more specifically, it is desirable that it is at least 0.05. By using an etching solution on the second light-guiding layer 27 with which layers with a high AlAs crystal composition ratio can be etched selectively, it is easy to expose the first light-guiding layer 26 located in the layer below it.

First Light-Guiding Layer

On the other hand, it is desirable that the AlAs crystal composition ratio of the first light-guiding layer 26 is as small as possible. The reason for that is as follows. In the gain region 34, the third light-guiding layer 29 is arranged directly on the first light-guiding layer 26, so that it is formed by regrowing the crystal on the first light-guiding layer 26. If the AlAs crystal composition ratio of the first light-guiding layer 26 is large, then the crystal regrowth interface oxidizes easily during the crystal regrowth. Such oxidation of the interface may cause an increase in the electrical resistance of the semiconductor laser. Consequently, it is desirable that the AlAs crystal composition ratio of the first light-guiding layer 26 is set to a small value, so that the interface hardly oxidizes in the crystal regrowth step. In the present embodiment, the AlAs crystal composition ratio of the first light-guiding layer 26 is 0.2. This makes it possible to prevent an increase of the resistance of the regrowth interface in the gain region 34 due to the crystal regrowth. Furthermore, it is desirable that the thickness of the first light-guiding layer 26 is as small as possible, so that it has almost no influence on the optical distribution in the transverse direction. In the present embodiment, the total thickness of the first light-guiding layer 26 and the second light-guiding layer 27-is set to 10 nm. Thus, by using a first light-guiding layer 26 whose AlAs crystal composition ratio is small and whose thickness is thin, it is possible to attain a regrowth interface of low resistance, without harming the controllability of the effective refractive index difference Δn.

Third Cladding Layer

Similarly, it is also desirable that the AlAs crystal composition ratio of the third cladding layer 30 is as small as possible. This is because the fourth cladding layer 32 in the stripe-shaped window 31a is regrown on the third cladding layer 30, so that if the AlAs crystal composition ratio of the third cladding layer 30 is large, the crystal regrowth interface is susceptible to oxidation, and such oxidation of the interface may cause an increase in the electrical resistance of the semiconductor laser. Furthermore, it is desirable that the AlAs crystal composition ratio of the third cladding layer 30 is at most 0.3, because then the etching selectivity with respect the Ga_{0.4}Al_{0.6}As current blocking layer 31 is high, the crystal regrowth on it becomes easy, and light of the laser oscillation wavelength is not absorbed. In the present invention, the AlAs crystal composition ratio of the third cladding layer 30 is set to 10 nm. Thus, it is possible to prevent an increase of the crystal regrowth interface. Furthermore, it is desirable that the third cladding layer 30 is as thin as possible, so that it has almost no influence on the optical distribution in the transverse direction. In the present embodiment, the thickness of the third cladding layer 30 is set to 10 nm. Thus, by making the AlAs crystal composition ratio small, and using a thin third cladding layer 30, it is possible to achieve a regrowth interface with low resistance, without harming the controllability of the effective refractive index difference Δn.

Diffraction Grating Layer

In view of high power operation, precise control of the effective refractive index difference Δn in the DBR region 36 in the order of 10⁻³ is necessary, and it is also preferable that the diffraction grating layer 28 is as thin as possible, so that it has almost no influence on the optical distribution in the transverse direction. However, if it is too thin, the coupling coefficient between the guided light and the diffraction grating becomes small, and the reflectance of the laser light in the DBR region 36 becomes small. Consequently, it is preferable that the thickness of the diffraction grating layer 28 is set to at least 5 nm and at most 60 nm. In the present embodiment, the thickness of the diffraction grating layer 28 is set to 20 nm.

Thus, the structure of the DBR semiconductor laser of the present embodiment is such that effective refractive index difference Δn can be controlled precisely in the order of 10⁻³ in all regions, that is, in the gain region 34, the phase control region 35 as well as the DBR region 36, making it possible to achieve a stable single transverse mode oscillation at high output power.

Second Cladding Layer

It is preferable the AsAs crystal composition ratio of the second cladding layer 25 is sufficiently higher than that of the active layer 24, such that the band gap of the second cladding layer 25 is sufficiently larger than the band gap of the active layer 24. Thus, it is possible to effectively confine carriers in the active layer 24. For example, to attain a laser oscillation in the 820 nm band, an AlAs crystal composition ratio of at least about 0.45 is desirable. In this embodiment, the AlAs crystal composition ratio of the second cladding layer 25 is 0.5.

Width of the Stripe-Shaped Window

In order to reduce the maximum optical density at the cleaved front surface 38 on the side of the gain region 34 to prevent the melt-down of the cleaved front surface 38, the width W of the stripe-shaped window 31a should be as broad as possible within the range in which the basic transverse mode can be attained. However, if it is too broad, then oscillation of transverse modes of higher harmonics may become possible, so that it is preferable that it is not too broad. Consequently, it is preferable that W is at least 2 μm and at most 5 μm. In the present embodiment, the width of the stripe-shaped window 31a is set to 3.5 μm.

Wavelength Selectivity

In the semiconductor laser of the present embodiment, the period of the diffraction grating formed in the diffraction grating layer 28 is an integer multiple of the medium-intrinsic wavelength. The wavelength of the laser light guided along the optical waveguide is selected by the Bragg reflection at the diffraction grating. The refractive index difference between the diffraction grating layer 28 and the third light-guiding layer 29 above it determines the wavelength selectivity due to the diffraction grating. It is desirable that the AlAs crystal composition ratio of the diffraction grating layer 28 is set to not more than 0.3 nm, so as to achieve a favorable wavelength selectivity and to facilitate the crystal regrowth on it, and also such that light of the laser oscillation wavelength is not absorbed. In the present embodiment, the AlAs crystal composition ratio of the diffraction grating layer 28 is 0.2. On the other hand, it is desirable that the AlAs crystal composition ratio of the third light-guiding layer 29 is at least 0.5m, so that a sufficient refractive index difference to the diffraction grating layer 28 can be achieved, which is necessary for a single longitudinal mode. In the present embodiment, the AlAs crystal composition ratio of the third light-guiding layer 29 is 0.5.

1C. Steps for Manufacturing the DBR Semiconductor Laser

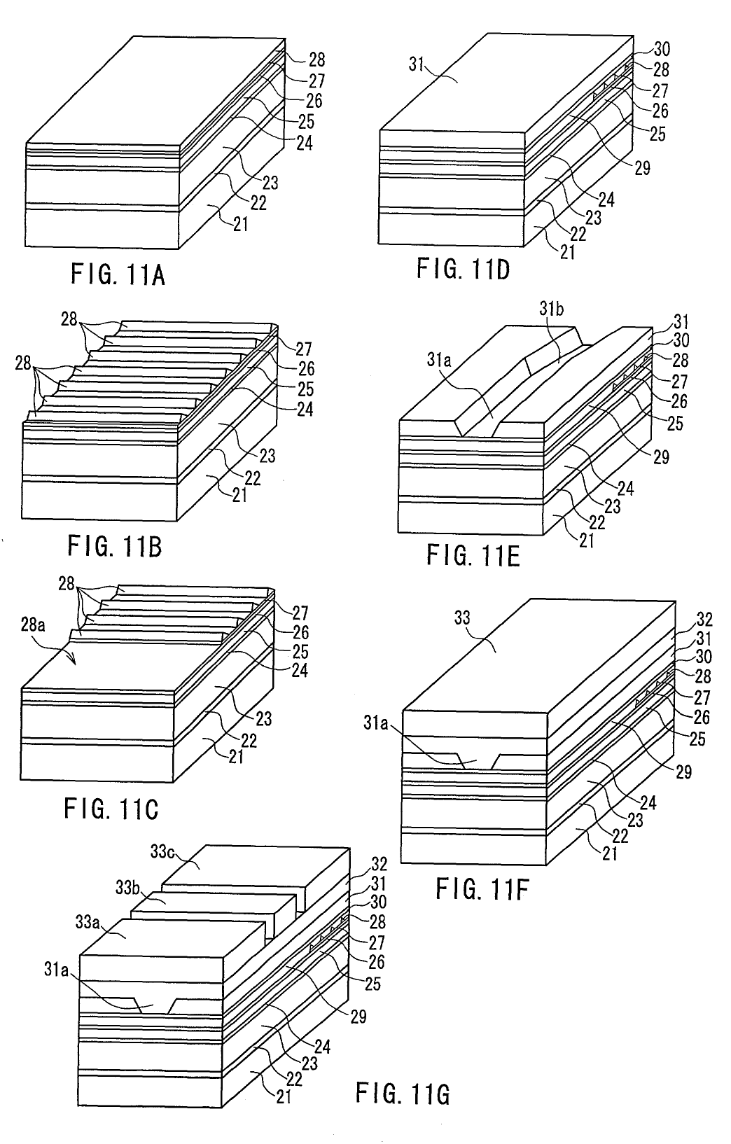

FIGS. 11A to 11G are perspective views of the steps for manufacturing the DBR semiconductor laser according to the present embodiment.

As shown in FIG. 11A, in a first crystal growth step with MOCVD or MBE, the n-type GaAs buffer layer 22 (0.5 μm thickness), the n-type Ga_{0.5}Al_{0.5}As first cladding layer 23 (1 μm thickness), the active layer 24 of multiple quantum wells of Ga_{0.7}Al_{0.3}As barrier layers and GaAs well layers, the p-type Ga_{0.4}Al_{0.5}As second cladding layer 25 (0.08 μm thickness), the p-type Ga_{0.7}Al_{0.3}As first light-guiding layer 26 (0.01 μm thickness), the p-type Ga_{0.6}Al_{0.6}As second light-guiding layer 27 (0.01 μm thickness) and the p-type Ga_{0.8}Al_{0.2}As diffraction grating layer 28 (0.02 μm thickness) are layered on the n-type GaAs substrate 21.

The active layer 24 uses unstrained multiple quantum wells in the present embodiment, but it is also possible to use strained quantum wells or a bulk active layer. Furthermore, there is no particular limitation regarding the conductivity type of the active layer 4, and it can be p-type, n-type or undoped.

Here, the diffraction grating layer 28 is formed above the active layer 24, so that the crystallinity of the active layer 24 is not decreased due to the crystal regrowth, and a production at high yield is possible.

Next, as shown in FIG. 11B, a diffraction grating having a certain period in the optical resonance direction is formed in the diffraction grating layer 28 by interference exposure, electron beam exposure or the like and wet etching or dry etching. In particular when forming the diffraction grating by wet etching, since the difference between the AlAs crystal composition ratios of the p-type Ga_{0.8}Al_{0.2}As diffraction grating layer 28 and the p-type Ga_{0.4}Al_{0.6}As second light-guiding layer 27 is large at 0.4, it is possible to etch only the diffraction grating layer 28 by using an etching solution that selectively etches layers with a small AlAs crystal composition ratio, so that it is possible to let the second light-guiding layer 27 function as an etching stop layer.

Next, as shown in FIG. 11C, a portion of the diffraction grating layer 28 is removed by wet etching or dry etching, forming the diffraction grating layer non-formation region 28a. This diffraction grating layer non-formation region serves as the gain region 34 and the phase control region 35, and the region where the diffraction grating layer 28 has not been removed (diffraction grating layer formation region) serves as the DBR region 36. Since the difference between the AlAs crystal composition ratios of the p-type Ga_{0.4}Al_{0.6}As second light-guiding layer 27 and the p-type Ga_{0.8}Al_{0.2}As first light-guiding grating layer 26 is large at 0.4, it is possible to let the p-type Ga_{0.8}Al_{0.2}As first light-guiding grating layer 26 function as an etching stop layer by using an etching solution that selectively etches layers with a large AlAs crystal composition ratio. Furthermore, during the regrowth, the gain region 34 and the phase control region 35 are regrown on a layer with small AlAs crystal composition ratio, so that the oxidation of the regrowth interface can be prevented, and deterioration of the crystallinity of the regrown layers can be inhibited.

Next, since the AlAs crystal composition ratio of the first light-guiding layer 26 is small, an etching solution etching selectively only layers with a high AlAs crystal composition ratio is used, and only the exposed second light-guiding layer 27 is etched, exposing the first light-guiding layer 26. This increases the shape controllability for the diffraction grating.

Next, in a second crystal growth step, the p-type Ga_{0.5}Al_{0.5}As third light guiding layer 29 (0.05 μm thickness), the p-type Ga_{0.8}Al_{0.2}As third cladding layer 30 (0.01 μm thickness), and the n-type Ga_{0.4}Al_{0.6}As current blocking layer 31 (0.6 μm thickness) are formed on the diffraction grating layer 28 and the first light-guiding layer 26 in the diffraction grating layer non-formation region, as shown in FIG. 11D. It should be noted that when the current blocking layer 31 is thin, the confinement of the light in the transverse direction may be insufficient, and the transverse mode may become unstable, so that it is desirable that the thickness of the current blocking layer 31 is at least 0.4 μm.

Subsequently, the stripe-shaped window 31a for current constriction is formed by etching in the Ga_{0.4}Al_{0.6}As current blocking layer 31, as shown in FIG. 11E. During the etching, the stripe-shaped window 31a is etched with a bend near the cleaved rear surface 37, so that the waveguide forms a 5° angle with the normal on the cleaved rear surface 37 on the side of the DBR region 36. This makes it possible to lower the effective reflectance at the cleaved rear surface 37 to a level of less than 10⁻⁶. The width W of the stripe-shaped window 31a was set to 3.5 μm in order to widen the optical distribution as much as possible in the transverse direction. During the etching, it is possible to stop the etching at the Ga_{0.8}Al_{0.2}As third cladding layer 30 by using an etchant such as hydrofluoric acid, which selectively etches layers with high AlAs crystal composition ratio. Thus, a semiconductor laser suitable for mass production can be attained without irregularities in its characteristics due to etching irregularities and with high yield.

For the groove shape of the stripe-shaped window 31a, a regular mesa shape is preferable to an inverted mesa shape. This is because with an inverted mesa shape, the fill-up-type crystal growth on top of the inverted mesa shape is more difficult than for a regular mesa shape, which may lead to a decrease in the yield caused by a decrease in properties.

Next, in a third crystal growth step, on the current blocking layer 31 including the stripe-shaped window 31a, the p-type Ga_{0.44}Al_{0.56}As fourth cladding layer 32 (2 μm thickness) and the p-type GaAs contact layer 33 (2 μm thickness) are formed, as shown in FIG. 11F. With this structure, it is possible to achieve an effective refractive index difference Δn of 3.5×10⁻³ between inside and outside the stripe-shaped window 31a. Thus, it is possible to confine the optical distribution stably within the stripe-shaped window 31a with a width W of 3.5 μm even during high-power output, and it becomes possible to achieve a stable basic transverse mode oscillation up to high-power outputs.

Then, a contact layer 33 partitioned into three regions, namely the contact layers 33a to 33c for the gain region 34, the phase control region 35 and the DBR region 36, is formed by wet etching or by dry etching, as shown in FIG. 11G.

Lastly, the cleaved front surface 38 from which the laser light is emitted is provided with a coating with a low reflectance of 3%, so as to allow high-power operation. On the side of the cleaved rear surface 37 the waveguide is tilted with respect to the normal on the cleaved rear surface 37, so that the reflectance at the cleaved rear surface 16 is effectively set to a very low value of less than 10⁻⁶, but in order to prevent reflection reliably at the cleaved rear surface 16, it is desirable that the cleaved rear surface 37 is provided with a non-reflectance coating of not more than 1% reflectance. Thus, the longitudinal mode control in the diffraction grating can be carried out even more reliably.

Sixth Embodiment

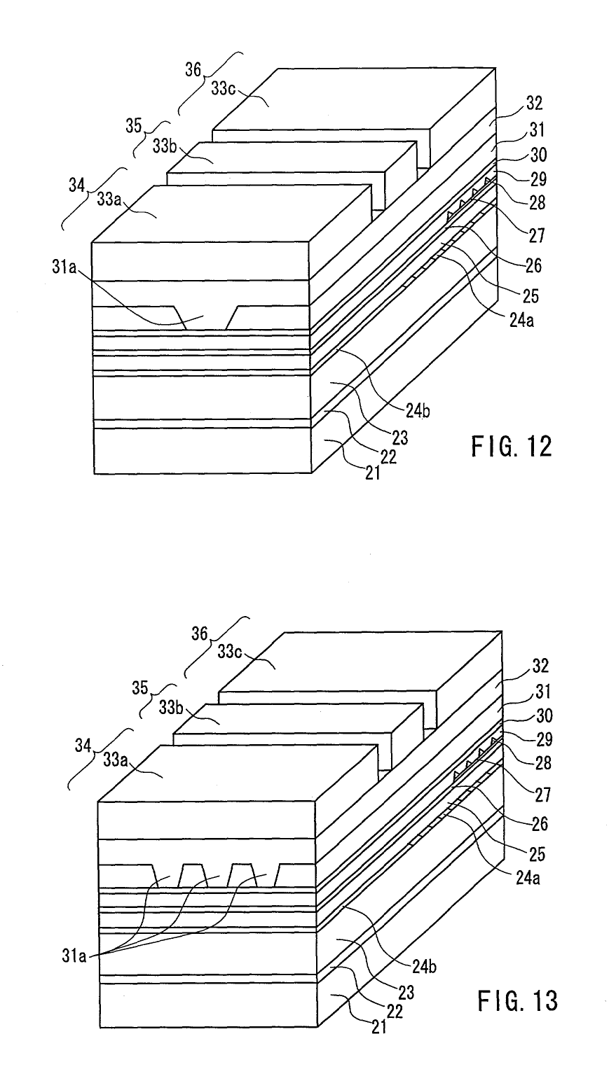

FIG. 12 is a perspective view of a DBR semiconductor laser incorporating a diffraction grating within a waveguide in accordance with a second embodiment of the present invention. In this DBR semiconductor laser, the active layer of multiple quantum wells of Ga_{0.7}Al_{0.3}As barrier layers and GaAs well layers is different regarding the phase control region 35, the DBR region 36 and the gain region 34, but other aspects of the configuration are analogous to the DBR semiconductor laser described in the fifth embodiment.

The following is an explanation of the active layer in the DBR semiconductor laser of the present embodiment.

The active layer 24a of the DBR region 36 and the phase control region 35 is disordered by ion implantation or diffusion of impurities, and its band gap is larger than the band gap of the active layer 24b in the gain region 34. Consequently, the laser light emitted in the gain region 34 is not absorbed by the active layer 24a in the DBR region 36 and the phase control region 35, so that an effect is attained in which the emission efficiency of the DBR semiconductor laser as well as the coupling efficiency between the diffraction grating and the laser light are both improved. Furthermore, in this situation, it is desirable that the band gap wavelength corresponding to the band gap of the active layer 24a in the DBR region 36 and the phase control region 35 is as short as possible, so that the light emitted when current is supplied to the DBR region 36 or the phase control region 35 has no influence on the optical characteristics of the gain region 34. However, when this band gap wavelength is made too short, then the waveguide losses in the DBR region 36 and the phase control region 35 become large. Consequently, it is necessary that the wavelength is not made too short. More specifically, it is desirable that the active layer 4a is disordered, such that its band gap wavelength is at least 10 nm and at most 80 nm shorter than the band gap wavelength of the active layer 24b in the gain region 34. In this embodiment, the active layer 24a of the DBR region 36 and the phase control region 35 is disordered, so that the band gap wavelength of the DBR region 15 and the phase control region 14 is short at 15 nm. Thus, the wavelength loss in the DBR region 36 and the phase control region 35 becomes less than 20 cm⁻¹.

In this structure, the current supplied from the p-type GaAs contact layer 33a is confined by the n-type Ga_{0.4}Al_{0.6}As current blocking layer 31 to within the stripe-shaped window 31a, and the optical emission occurs in the active layer 24b below the p-type GaAs contact layer 33a. The generated light is subjected to a distributed Bragg reflection by the diffraction grating layer 28, and as a result of the wavelength selection, a single longitudinal mode oscillation is achieved. By changing the value of the current supplied to the DBR region 36 and the phase control region 35, the laser oscillation wavelength sustains and controls a single longitudinal mode oscillation.

Seventh Embodiment

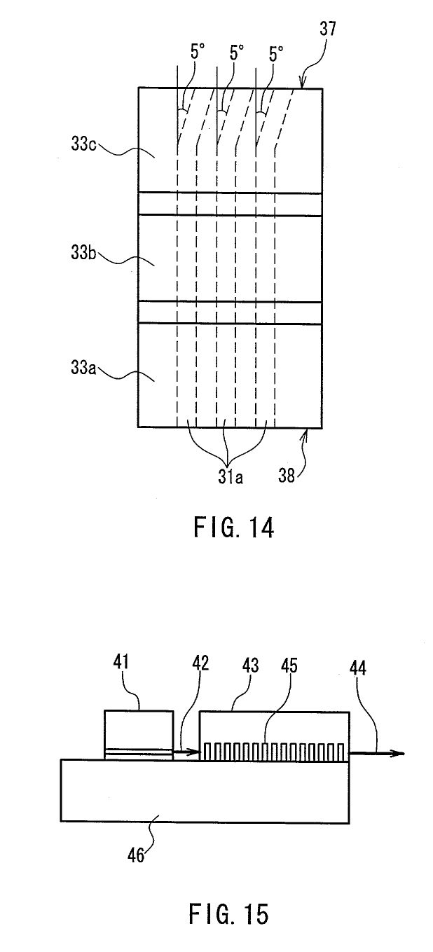

FIG. 13 is a perspective view of a DBR semiconductor laser incorporating a diffraction grating within a waveguide in accordance with a seventh embodiment of the present invention. This DBR semiconductor laser has the same configuration as the DBR semiconductor laser explained in the fifth embodiment, except that in this DBR semiconductor laser, in the active layer of multiple quantum wells of Ga_{0.7}Al_{0.3}As barrier layers and GaAs well layers, the active layer 24a in the phase control region 35 and the DBR region 36 is disordered, whereas the active layer 24b in the gain region 34 is not disordered, and a plurality of stripe-shaped windows 31a are provided see FIG. 14 as well.

The providing of a disordered active layer 24a in the phase control region 35 and the DBR region 36 and an active layer 24b that is not disordered in the gain region 34 is as explained in the second and the sixth embodiments, whereas the providing of the plurality of stripe-shaped windows 31a is as explained in the third embodiment.

Eighth Embodiment

The following is an explanation of a DBR semiconductor laser as in the first to seventh embodiments, applied to an optical element, such as a second harmonic generation element.

FIG. 15 illustrates a second harmonic generation element, in which a high-power DBR semiconductor laser 41 as explained in the first to seventh embodiments and a non-linear optical element 43 generating a second harmonic are integrated on a substrate 46. In this element, excitation light 42 that is emitted from the DBR semiconductor laser 41 is irradiated onto the non-linear optical element 43, and coupled into the waveguide formed in the non-linear optical element 43. In this situation, emitted light is diffracted by the diffraction element 45 such that the phase of the second harmonic light 44 matches the phase of the excitation light 42. As a result, the conversion efficiency from excitation light 42 to second harmonic light 44 is increased, and second harmonic light 44 can be obtained from the non-linear optical element 43. In order to make sure that the far-field pattern of the second harmonic light 44 is not reflected by the semiconductor, disturbing the pattern shape, the edge of the substrate 46 and the edge of the non-linear optical element 43 should be as close together as possible, within a distance of 10 μm, or the edge of the non-linear element 43 should protrude from the substrate 46. Furthermore, the distance between the DBR semiconductor laser 41 and the non-linear optical element 43 should be as close as possible, because this increases the coupling of excitation light 42 into the waveguide formed in the non-linear optical element 43. The DBR semiconductor laser 41 of the present invention does not have a thick diffraction grating layer in its gain region and the optical distribution is almost unaffected, so that it is possible to control the optical distribution with great precision. Consequently, it is possible to set the vertical spread angle to not more than 20° and even if the distance between the DBR semiconductor laser 41 and the non-linear optical element 43 is more than 2 μm, a high coupling efficiency between the excitation light 42 and waveguide of the non-linear optical element 43 can be attained. Therefore, the range within which the distance between the DBR semiconductor laser 41 and the non-linear optical element 43 should be controlled can be widened, and a second harmonic light 44 with high efficiency can be obtained with high reproducibility. For the material of the substrate 46, it is possible to use semiconductors such as Si, SiC, AIN, insulating materials such as glass or plastic substrates, resin materials, or any other suitable material that is flat and on which an electrode pattern can be formed. As for the material of the non-linear optical element 43, it is possible to generate second harmonic waves with materials such as LiNbO₃ and KTP that are non-linear. In particular, when using a DBR semiconductor laser with an oscillation wavelength of 820 nm and using LiNbO₃ for the non-linear optical element, it is possible to attain high-power laser light in the blue-violet wavelength range of 410 nm.

First Example of Optical Element Using a Second Harmonic Generation Element

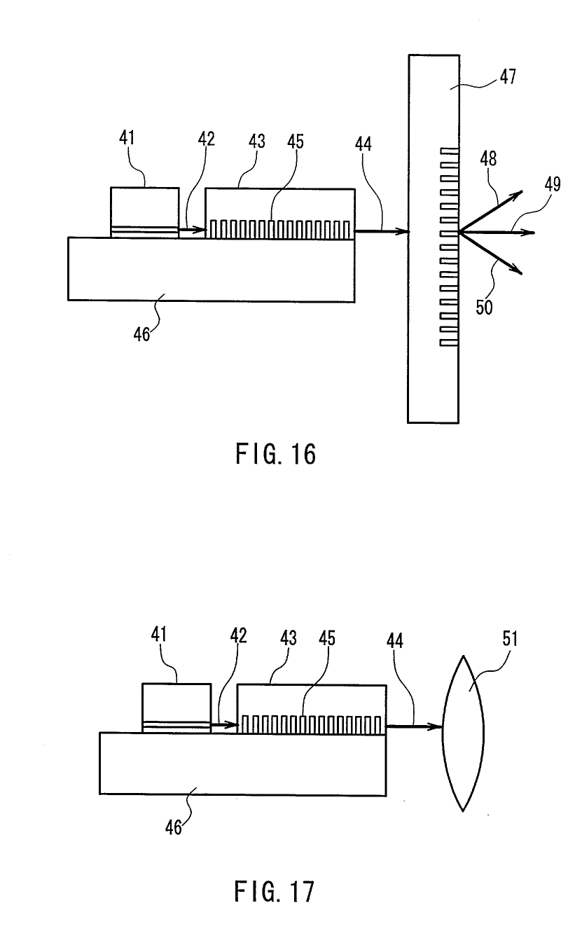

FIG. 16 shows an optical element using a diffraction grating 47 for splitting the second harmonic light 44 emitted from the second harmonic generation element shown in FIG. 15 into a plurality of emission directions. When this optical element is used as the light source of an optical pickup for an optical disk, then the O-order diffraction light 49 can be used for reading and writing bit information recorded onto the optical disk, and the −1-order diffraction light 48 and the +1-order diffraction light 50 can be used for the position detection of the tracks formed on the optical disk. In particular, when using a DBR semiconductor laser with an oscillation wavelength of 820 nm for the DBR semiconductor laser 41 and using LiNbO₃ for the non-linear optical element 43, it is possible to obtain high-power laser light in the blue-violet wavelength range of 410 nm, so that it can be applied as a light source of an optical pickup for a high-density optical disk system capable of reading and writing bit information.

Second Example of Optical Element Using a Second Harmonic Generation Element

FIG. 17 shows an optical element using a lens 51 so as to focus the second harmonic light 44 emitted from the second harmonic generation element shown in FIG. 15. With this configuration, when using the optical element as the light source of an optical pickup of an optical disk, it is possible to focus to the diffraction limit of the lens 51, so that bit information recorded on the optical disk can be read and written. In particular, when using a DBR semiconductor laser with an oscillation wavelength of 820 nm for the DBR semiconductor laser 41 and using LiNbO₃ for the non-linear optical element 43, it is possible to attain high-power laser light in the blue-violet wavelength range of 410 nm, so that it can be applied as a light source of an optical pickup for a high-density optical disk system capable of reading and writing bit information.

Third Example of Optical Element Using a Second Harmonic Generation Element

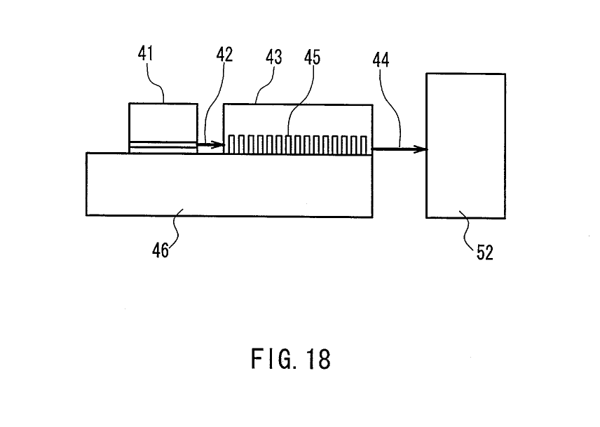

FIG. 18 shows an optical element using a birefringent optical element (birefringent element) 52 in the emission direction of the laser, in order to separate the second harmonic light 44 emitted from the second harmonic generation element shown in FIG. 15 into TE mode light and TM mode light with different polarization. By using this optical element, it is possible to retrieve light of one polarization direction, such as TE mode laser light, with high efficiency. In particular, when using a DBR semiconductor laser with an oscillation wavelength of 820 nm for the DBR semiconductor laser 41 and using LiNbO₃ for the non-linear optical element, it is possible to retrieve light of one polarization direction, such as only TE mode laser light, with high efficiency from high-power laser light in the blue-violet wavelength range of 410 nm. Such light sources with high polarization ratios are in demand as light sources of optical disk systems, in which the bit information recorded on the optical disk is recorded by the orientation of the magnetization. Consequently, the light source shown in FIG. 18 can be used as a light source for reading and writing in an optical disk system in which the magnetization orientation is recorded as information, as described above.

Fourth Example of Optical Element Using a Second Harmonic Generation Element

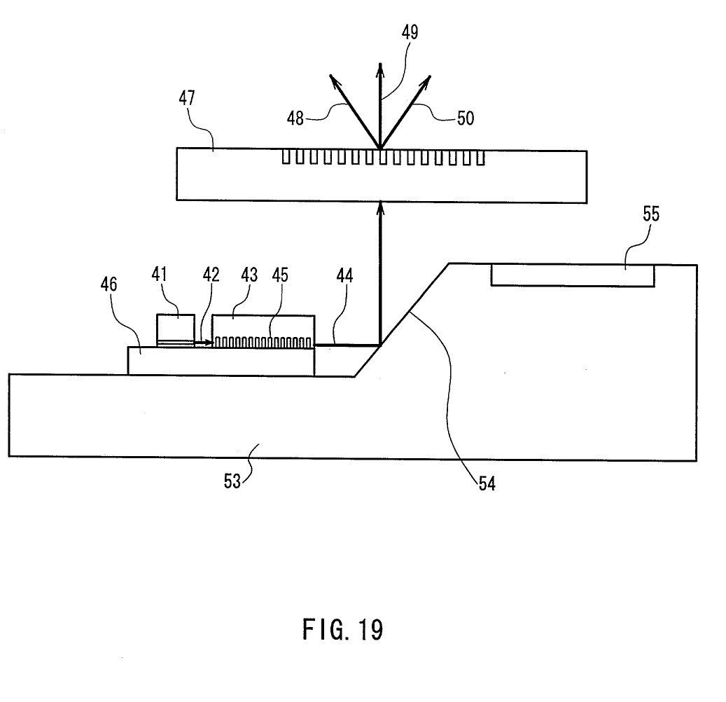

FIG. 19 shows an optical element, in which the second harmonic generation element shown in FIG. 15 is integrated on a substrate 53 provided at least at one location with a light-receiving element 55 and with a mirror 54 that reflects light emitted from the second harmonic generation element in a direction perpendicular to the substrate surface, and using a diffraction grating 47 for splitting the reflected light into a plurality of emission directions. When using this optical element as a light source for an optical pickup, the light-receiving portion (light-receiving element 55) that is necessary for the signal detection of the optical pickup and the light-emitting portion (second harmonic generation element) are integrated on a single substrate, so that it is possible to make the optical pickup smaller. Moreover, the O-order diffraction light 49 can be used for reading and writing bit information recorded onto the optical disk, and the −1-order diffraction light 48 and the +1-order diffraction light 50 can be used for the position detection of the tracks formed on the optical disk. In particular, when using a DBR semiconductor laser with an oscillation wavelength of 820 nm for the DBR semiconductor laser 41 and using LiNbO₃ for the non-linear optical element 43, it is possible to obtain high-power laser light in the blue-violet wavelength range of 410 nm, so that it is possible to achieve a small and thin light source that is suitable as an optical pickup for a high-density optical disk system in which information can be read and written.

Fifth Example of Optical Element Using a Second Harmonic Generation Element

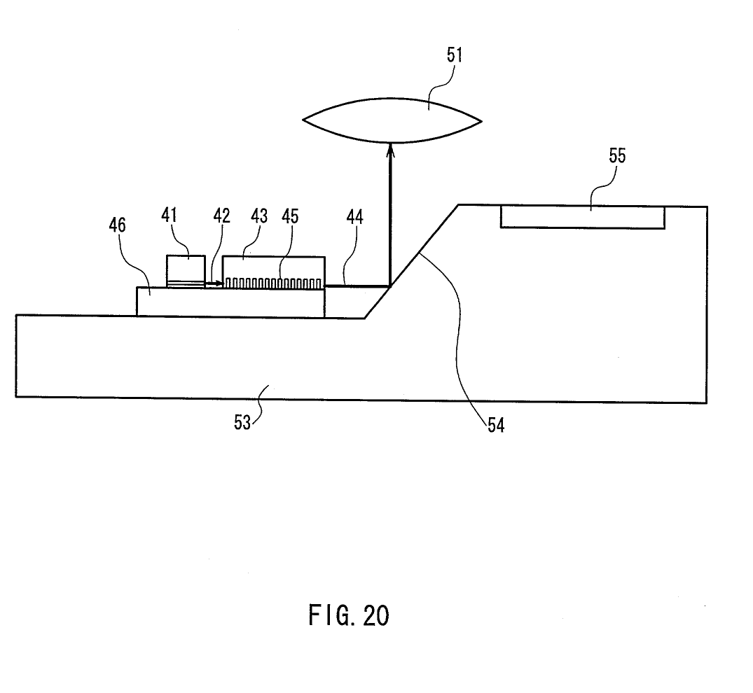

FIG. 20 shows an optical element, in which the second harmonic generation element shown in FIG. 15 is integrated on a substrate 53 provided at least at one location with a light-receiving element 55 and with a mirror 54 that reflects light emitted from the second harmonic generation element into a direction perpendicular to the substrate surface, and using a lens 51 for focusing the reflected light. When using this optical element as a light source for an optical pickup, the light-receiving portion (light-receiving element 55) that is necessary for the signal detection of the optical pickup and the light-emitting portion (second harmonic generation element) are integrated on a single substrate, so that it is possible to make the optical pickup smaller. With this configuration, it is possible to focus to the diffraction limit of the lens 51, so that bit information recorded on the optical disk can be read and written. In particular, when using a DBR semiconductor laser with an oscillation wavelength of 820 nm for the DBR semiconductor laser 41 and using LiNbO₃ for the non-linear optical element 43, it is possible to attain high-power laser light in the blue-violet wavelength range of 410 nm, so that it is possible to achieve a small and thin light source that is suitable as an optical pickup for a high-density optical disk system in which information can be read and written.

Sixth Example of Optical Element Using a Second Harmonic Generation Element

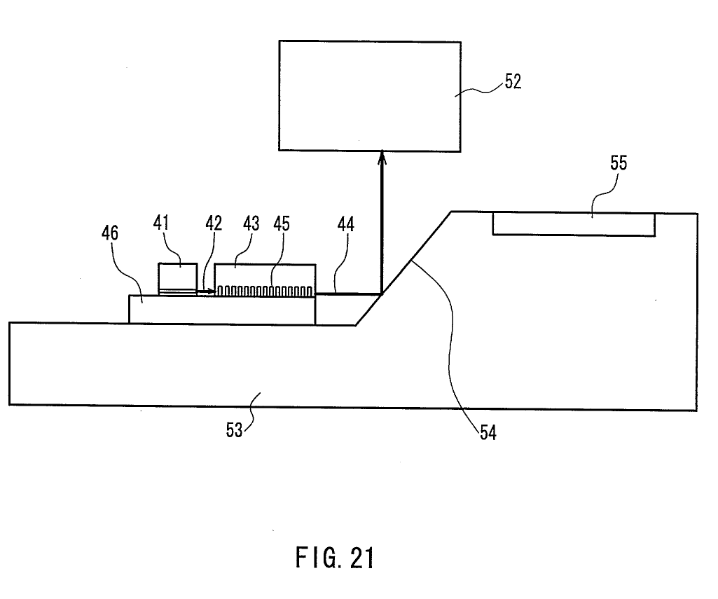

FIG. 21 shows an optical element, in which the second harmonic generation element shown in FIG. 15 is integrated on a substrate 53 provided at least at one location with a light-receiving element 55 and with a mirror 54 that reflects light emitted from the second harmonic generation element in a direction perpendicular to the substrate surface, and using a birefringent optical element (birefringent element) 52 in the emission direction of the laser, in order to separate the reflected light into TE mode light and TM mode light with different polarization directions. When using this optical element as a light source for an optical pickup, the light-receiving portion (light-receiving element 55) that is necessary for the signal detection of the optical pickup and the light-emitting portion (second harmonic generation element) are integrated on a single substrate, so that it is possible to make the optical pickup smaller. Furthermore, with this configuration, it is possible to retrieve light of one polarization direction, such as TE mode laser light, with high efficiency. In particular, when using a DBR semiconductor laser with an oscillation wavelength of 820 nm for the DBR semiconductor laser 41 and using LiNbO₃ for the non-linear optical element, it is possible to retrieve light of one polarization direction, such as only TE mode laser light, with high efficiency from high-power laser light in the blue-violet wavelength range of 410 nm. Such light sources with high polarization ratios are in demand as light sources of optical disk systems, in which the bit information recorded on the optical disk is recorded by the orientation of the magnetization. Consequently, the optical element shown in FIG. 21 can be used as a small and thin light source for reading and writing in an optical disk system in which the magnetization orientation is recorded as information, as described above.

For the material of the substrate 53, it is possible to use group IV semiconductor materials, group III nitride semiconductor materials, group III-V semiconductor materials, or groups II-VI semiconductor materials. Suitable examples of group IV semiconductor materials include Si and SiC. Group III nitride semiconductor materials include at least nitride as the group V element, include at least one of B, In, Al and Ga as the group III element, and also may include As, P or As as group V semiconductor materials. Group III-V semiconductor materials are semiconductor materials that include at least one of B, In, Al and Ga as the group III element and at least one of As, P and As as the group V element, such as InGaAIP-based materials or InGaAsP-based materials. Group II-VI semiconductor materials are materials that include at least one of Zn and Cd as the group II element and at least one of S, Se and Mg as the group V element, such as ZnSMgSe. As long as these semiconductor are pn-controllable, they can be used to form the light-receiving portion, so that they can be applied. Furthermore, if they are not pn-controllable, it is possible to attain similar effects by integrating a light-receiving element on glass or a resinous material, such as plastic.

In the above-described embodiments, a semiconductor laser using a GaAlAs-based material was illustrated as an example, but is possible to attain similar effects by using other materials, in particular a group III nitride-based semiconductor material including at least nitrogen as the group V element and at least one of B, In, Al and Ga as the group III element and possibly further including As, P or As as group V elements; a group III-V semiconductor material including at least one of B, In, Al and Ga as the group III element and at least one of As, P and As as the group V element, such as InGaAlP-based materials or InGaAsP-based materials; or a group II-VI semiconductor material including at least one of Zn and Cd as the group II element and at least one of S, Se and Mg as the group V element, such as ZnSMgSe.

In the above-described embodiments, a semiconductor laser using a waveguide structure having an effective refractive index waveguide mechanism was illustrated as an example, but it is also possible to apply the present invention to any other waveguide structure, such as structures provided with a current blocking function by ion implantation or diffusion of impurities, and ridge waveguide structures in which a ridge-shaped cladding layer is formed for optical confinement in the transverse direction.

In the above-described embodiments, an effective refractive index waveguide semiconductor laser using an AlGaAs current blocking layer having a regular mesa shape and having a band gap that is larger than the band gap of the active layer was illustrated as an example, but it is possible to use any suitable structure that has an effective refractive index mechanism. Furthermore, for the shape of the current-blocking layer, it is also possible to use an inverted mesa shape, and for the material of the current blocking layer, it is possible to use any material that has a band gap larger than the active layer, such as AlGaInP or the insulating materials SiN or SiO₂.

In the above-described embodiments, a cladding layer is formed on the stripe-shaped window formed in the current-blocking layer, but similar effects can also be attained when forming a ridge-shaped cladding layer, and forming a current-blocking layer on top of that.

For the structure of the active layer, use of a quantum well structure has been described, but it is also possible to use a bulk active layer made of a single material.

As for the structure of the laser, the present invention can be applied to any semiconductor laser, such as DFB (Distributed Feedback) semiconductor lasers, semiconductor lasers that are partitioned by electrodes in the optical resonance direction, DBR lasers, surface emitting lasers, or BH (buried heterojunction) lasers.

Furthermore, it is also possible to achieve a small, thin, high-power optical pickup by combining the semiconductor laser of the present invention with an optical component having a diffraction function such as a hologram optical element, lens or optical element, and an electronic component of a material having birefringence, such as PbO or a non-linear optical material like LiNbO₃, and integrating them into a single element.

Furthermore, in the embodiments shown in FIG. 19 to FIG. 21, examples were illustrated in which the substrate 53 including the light-receiving portion, the diffraction grating 47, the lens 50 and the birefringent optical element 52 are provided separately, but by directly integrating the diffraction grating 47, the lens 51 and the birefringent optical element 52 on the substrate 53 including the light-receiving portion, it is possible to achieve a light source for an optical pickup that is even smaller and thinner.

As explained above, the present invention achieves a DBR semiconductor laser allowing a precise control of the optical distribution in which a high-power operation can be realized with high reliability. Furthermore, in the production of the DBR semiconductor laser using an AlGaAs-based material, the regrowth is performed on a layer with a low AlAs crystal composition ratio, so that a deterioration of the crystallinity after the regrowth can be prevented. If this DBR semiconductor laser is provided with an effective refractive index waveguide structure, the operation current can be reduced, and an even higher output power can be achieved. Thus, with the semiconductor laser of the present invention, it is possible to achieve, with high reproducibility, a super-high output DBR semiconductor laser, which used to be difficult to attain conventionally.

Furthermore, by combining the DBR semiconductor laser of the present invention and a non-linear optical element generating a second harmonic, it is possible to attain, with high reproducibility, a high-power short-wavelength light source. In particular, when integrating the DBR semiconductor laser of the present invention with a non-linear optical element generating a second harmonic and a light-receiving element on a single substrate, it is possible to attain a light source for a small and thin optical pickup, with high reliability. In the DBR semiconductor laser of the present invention, the optical distribution can be controlled precisely, so that the optical distribution can be controlled such that the optical coupling efficiency with the waveguide of the non-linear optical element can be made high, so that a high-efficiency short-wavelength light source can be achieved.

The invention may be embodied in other specific forms without departing from the spirit or essential characteristics thereof. The embodiments disclosed in this application are to be considered in all respects as illustrative and not restrictive, the scope of the invention being indicated by the appended claims rather than by the foregoing description. All changes that come within the meaning and range of equivalency of the claims are intended to be embraced therein.

What is claimed is:

1. A semiconductor laser comprising:
an active layer emitting light due to electron-hole recombination caused by a supplied current;
a first semiconductor layer, which is provided above the active layer and which confines carriers supplied to the active layer as well as light emitted in the active layer within the active layer;
a second semiconductor layer, which is provided above the first semiconductor layer and which comprises a diffraction grating;
wherein the second semiconductor layer is arranged in a region other than at least a predetermined region, said predetermined region being a region arranged in opposition to an optical waveguide of the active layer in a gain region provided, with respect to an optical resonance direction, on a side of a light emission end face of the laser.

2. The semiconductor laser according to claim 1, further comprising a third semiconductor layer, which is provided between the first semiconductor layer and the second semiconductor layer, and which is less susceptible to oxidation than the first semiconductor layer.

3. The semiconductor laser according to claim 1, wherein the second semiconductor layer is arranged in a region other than the gain region.

4. The semiconductor laser according to claim 1,
further comprising a phase control region, which is provided between the gain region and a Bragg reflection region causing a Bragg reflection with the diffraction grating, and which continuously changes an oscillation wavelength of a laser light by controlling a phase of the laser light; and
wherein the second semiconductor layer is arranged in a region other than a region arranged in opposition to the optical waveguide of the active layer in the phase control region.

5. The semiconductor laser according to claim 4, wherein the second semiconductor layer is arranged in a region other than the phase control region.

6. The semiconductor laser according to claim 1, further comprising a current blocking layer, which includes a stripe-shaped window provided along the optical waveguide and which narrow current supplied.

7. The semiconductor laser according to claim 6, wherein a band gap of the current blocking layer is larger than a band gap of the active layer.

8. The semiconductor laser according to claim 6,
further comprising a fourth semiconductor layer provided above the current blocking layer and within the stripe-shaped window;
wherein a band gap of the current blocking layer is larger than a band gap of the fourth semiconductor layer.

9. The semiconductor laser according to claim 6, wherein an effective refractive index difference between inside and outside of the stripe-shaped window is at least 3×10⁻³ and at most 5×10⁻³.

10. The semiconductor laser according to claim 6, wherein the stripe-shaped window intersects with an end face opposite the light emission end face of the laser such that an angle between the stripe direction of the stripe-shaped window and a normal on that end face is greater than 0°.

11. The semiconductor laser according to claim 6, wherein a width of the stripe-shaped window is at least 2 μm and at most 5 μm.

12. The semiconductor laser according to claim 6, wherein the current blocking layer comprises a plurality of stripe-shaped windows, which are arranged parallel to one another.

13. The semiconductor laser according to claim 12, wherein a spacing between neighboring stripe-shaped windows is less than a distance at which the optical distributions interfere with one another.

14. The semiconductor laser according to claim 13, wherein a spacing between neighboring stripe-shaped windows is at most 5 μm.

15. The semiconductor laser according to claim 1, wherein a Bragg reflection wavelength of the diffraction grating is at least 20 nm longer than a band gap wavelength of the active layer.

16. The semiconductor laser according to claim 1, wherein the active layer arranged in a region other than the gain region has a band gap that is smaller than that of the active layer arranged within the gain region.

17. The semiconductor laser according to claim 16, wherein the active layer arranged in a region other than the gain region is disordered by ion implantation or diffusion of impurities.

18. The semiconductor laser according to claim 16, wherein the active layer arranged in a region other than the gain region has a band gap wavelength that is at least 10 nm and at most 80 nm shorter than that of the active layer arranged in the gain region.

19. The semiconductor laser according to claim 2, further comprising a fifth semiconductor layer, which is provided between the second semiconductor layer and the third semiconductor layer, and wherein a selective etching ratio to the second semiconductor layer is larger than a selective etching ratio between the second semiconductor layer and the third semiconductor layer.

20. An optical element comprising:
the semiconductor laser according to claim 1; and
a non-linear optical element that shortens a wavelength of light emitted from the semiconductor laser.

21. The optical element according to claim 20, further comprising a diffraction grating for splitting light emitted from the non-linear element into a plurality of directions.

22. The optical element according to claim 20, further comprising a focusing lens for focusing light emitted from the non-linear optical element.

23. The optical element according to claim 20, further comprising a birefringent element for separating light emitted from the non-linear optical element into light of a plurality of waveguide modes of different polarization directions.

24. An optical pickup comprising:
the semiconductor laser according to claim 1,
a non-linear optical element that shortens a wavelength of light emitted from the semiconductor laser; and
a light-receiving portion for detecting a signal of information recorded on a recording medium.

25. The optical pickup according to claim 24, further comprising a diffraction grating for splitting light emitted from the non-linear optical element into a plurality of directions.

26. The optical pickup according to claim 24, further comprising a focusing lens for focusing light emitted from the non-linear optical element.

27. The optical pickup according to claim 24, further comprising a birefringent element for separating light emitted from the non-linear optical element into light of a plurality of waveguide modes of different polarization directions.

28. The optical pickup according to claim 24, wherein the semiconductor laser, the non-linear element, and the light-receiving portion are arranged on a single substrate.
